(19) United States
(12) Patent Application Publication
(10) Pub. No.: US 2008/0024173 A1
(43) Pub. Date: Jan. 31, 2008

(54) Semiconductor integrated circuit including a malfunction detection circuit, and a design method for the same

(76) Inventors: Masaaki Nagai, Osaka (JP); Kenji Tutumi, Osaka (JP); Hideshi Nakazawa, Osaka (JP)

Correspondence Address: MCDERMOTT WILL & EMERY LLP, 600 13TH STREET, NW, WASHINGTON, DC, 20005-3096, US

(21) Appl. No.: 11/878,520

(22) Filed: Jul. 25, 2007

(30) Foreign Application Priority Data
Jul. 25, 2006 (JP) 2006-202460

(51) Int. Cl. H03K 5/19; G06F 17/50

(52) U.S. Cl. 327/20; 716/6

(57) ABSTRACT

A malfunction detection circuit realized by a simple circuit structure is incorporated into a semiconductor integrated circuit without increasing the scale thereof, in order to prevent loss etc. of data due to a malfunction of the semiconductor integrated circuit. Malfunctions can be prevented without relying on measuring temperature or power supply voltage which are analog values, thereby improving the reliability of the semiconductor integrated circuit. A detection-target flip-flop in a function block is synchronized to a clock, and another flip-flop is synchronized to a clock whose phase has been delayed behind or advanced ahead of the former clock. A logic operation is performed using output from both flip-flops to determine whether a latch operation has been performed at an appropriate clock pulse edge in a clock pulse train. The malfunction countermeasure is performed if the latch operation is determined to have been performed at an inappropriate clock pulse edge.

### BACKGROUND OF INVENTION

1. Field of the Invention

The present invention relates to technology for improving the reliability of a semiconductor integrated circuit.

2. Related Art

In recent years, emphasis has been placed on the reliability of semiconductor chips, and a number of technologies for preventing malfunctions in semiconductor integrated circuits have been adopted. The main factors that influence the circuit characteristics of semiconductor integrated circuits include the temperature in or around the semiconductor chip, and the internal or external-power supply voltage.

In general, the product specification of shipped semiconductor chips includes a guarantee for operation in a certain temperature range and voltage range. If the semiconductor chip is used beyond the product specification, the semiconductor integrated circuit may malfunction, thereby causing a loss of control in a processor operating with use of the semiconductor integrated circuit, which could lead to a reset and the loss of data.

The publicly known inventions taught in patent documents 1 and 2 are technology for preventing a malfunction in semiconductor integrated circuits.

Patent document 1 discloses a temperature sensor circuit in which a differential couple is formed from two MOS transistors having different ratios of the gate length to gate width, and a current mirror circuit is connected as the load to the differential couple transistors. The current mirror circuit is formed from two MOS transistors having different ratios of the gate length to gate width. The output of the current mirror circuit is fed to the differential couple transistors in feedback control so that the mirror ratio of the current mirror circuit is made equal to the drain current ratio between the differential couple transistors, and a voltage proportional to the temperature is obtained between the two inputs to the differential couple transistors. The temperature sensor circuit is realized by a CMOS transistor on a CMOS integrated circuit. The temperature sensor circuit has various applications, and if the temperature of the semiconductor integrated circuit is to be judged against a certain reference temperature a voltage comparison circuit and a reference voltage generation circuit, for example, are included in order to perform a comparison using the output of the temperature sensor circuit.

Patent document 2 discloses a power supply voltage detection circuit that includes a voltage division circuit that divides and outputs a power supply voltage, a reference voltage generation circuit that outputs a reference voltage, and a comparison circuit that compares the reference voltage and the voltage output by the voltage division circuit and outputs a result of the comparison.

Patent document 1: Japanese Patent Application Publication No. H05-45233

Patent document 2: Japanese Patent Application Publication No. H06-34676

### SUMMARY OF INVENTION

However, there are cases in which a reset occurs and data is lost, even when a semiconductor chip is not operating beyond the specification. In such cases, merely detecting temperature variations and voltage variations according to conventional technology cannot prevent data loss, and therefore conventional technology cannot ensure the prevention of data loss.

According to the aforementioned conventional technology, malfunction detection is performed with respect to variations in the temperature in or around the semiconductor chip and variations in the internal or external power supply voltage, and unexpected resets are said to be caused by localized temperature and power supply voltage variations at various places on the semiconductor chip. Detecting all such variations without fail would require providing the temperature sensors and comparison circuits disclosed in patent documents 1 and 2 all over the chip, which is not practical. This is because given that the conventional malfunction detection is based on temperature and power supply current which are analog values, elements must be incorporated for measuring such analog values, and there are limits to incorporation sites and degree of integration.

An aim of the present invention is to provide a semiconductor integrated circuit that can prevent malfunctions without relying on measuring temperature or power supply voltage which are analog values.

In over to solve the above issue, an integrated circuit including a malfunction detection circuit pertaining to the present invention is an integrated circuit including one or more circuit-integrated detection-target flip-flops, including: one or more detection circuits, each operable to detect that a different one of the detection-target flip-flops is performing a latch operation at an appropriate clock pulse edge in a clock pulse train, and that the one of the detection-target flip-flops is performing the latch operation at an inappropriate clock pulse edge which is one of delayed behind and advanced ahead of the appropriate-clock pulse edge; and an execution unit operable to execute a malfunction countermeasure when one of the detection circuits has detected that the corresponding detection-target flip-flop has performed the latch operation at the inappropriate clock pulse edge.

According to this structure, the detection circuit determines whether the latch operation has been performed at a predetermined edge in a clock signal or an edge that is before or after the predetermined edge, thereby enabling detecting a malfunction without relying on measurements of analog values, and enabling performing a malfunction countermeasure. Due to the ability to be formed from a logic element, the detection circuit for detecting whether the latch is early or delayed can be incorporated anywhere in the semiconductor integrated circuit, and the degree of integration can be increased. Given that the detection circuit is incorporated into the semiconductor integrated circuit, malfunctions can be detected in real-time, and the processor can be made to perform a malfunction counter measure such as backing up data to a RAM in order to prevent data loss.

Here, the integrated circuit may further include: one or more combinational circuits, each operable to output an output signal, wherein each of the detection-target flip-flops may be connected to an output of a different one of the combinational circuits, the appropriate clock pulse edge immediately may follow a timing when one of a setup and a hold in the output signal output by each of the combinational circuits has ended, and the inappropriate clock pulse edge may be, among a plurality of edges in the clock pulse train, an edge at which a predetermined time constraint of one of the setup and the hold is not satisfied.

The fact that the latch operation has been performed at a clock pulse edge that is behind or ahead of the predetermined edge can be detected as a malfunction of the semiconductor integrated circuit, since the setup or hold no longer satisfies the predetermined time constraint when the delay time in a combinational circuit changes.

Here, each of the detection circuits may include an other flip-flop that performs the latch operation at an edge in an other clock pulse train whose phase is one of delayed behind and advanced ahead of the clock pulse train that includes the appropriate clock pulse edge or inappropriate clock pulse edge at which the detection-target flip-flop corresponding to the detection circuit performs the latch operation, and in each of the detection circuits, the judgment whether the predetermined time constraint of one of the setup and the hold has been satisfied may be performed by executing a logic operation with use of output from the detection-target flip-flop that corresponds to the detection circuit and output from the other flip-flop included in the detection circuit.

Detecting whether the setup or hold satisfies the predetermined time constraint can be realized simply by adding flip-flops and a logic element. Since the flip-flops and logic elements can be added anywhere, malfunctions can be detected at arbitrary sites on the semiconductor integrated circuit.

Here, the predetermined time constraint of one of the setup and the hold may be judged to not be satisfied if (i) a temperature inside or around the integrated circuit is outside a predetermined temperature range, or (ii) a power supply voltage inside or outside the integrated circuit is outside a predetermined voltage range, and each of the detection circuits may have been placed behind, from among the one or more combinational circuits in the integrated circuit, a different combinational circuit that has one of a greatest temperature variation and a greatest voltage variation.

Since the main cause of a malfunction in a semiconductor integrated circuit is that the temperature or power supply voltage falls out of the product specification range, the circuit can be constituted so as to detect an error when circuit parameters change due to a variation in the temperature or power supply voltage. This enables detecting a malfunction of the semiconductor integrated circuit without performing a comparison with a reference temperature or a reference voltage.

Here, the integrated circuit may further include: a clock supply circuit that includes a plurality of buffer gates that are connected in a tree configuration, and a plurality of delay adjustment circuits, each operable to perform delay adjustment on an output of a different one of the buffer gates in a last level of the tree configuration, wherein in each of the detection circuits, the latch operation may have been performed by the other flip-flop in accordance with one of the outputs on which the delay adjustment has been performed.

Accurately synchronizing, delaying or advancing the clocks input to the malfunction detection circuit and detection-target circuit enables eliminating the influence of temperature variations and voltage variations on paths of the clocks that are input to the circuits.

Here, in each of the detection circuits, a predetermined time constraint of the other flip-flop included in the detection circuit may be longer than the predetermined time constraint of the detection-target flip-flop that corresponds to the detection circuit.

Pre-detecting a malfunction in the semiconductor integrated circuit can be performed by using the malfunction detection circuit that includes a flip-flop whose setup or hold time constraint is longer than the setup or hold time constraint of the detection-target flip-flop.

Here, each of the detection circuits may have been disposed at a different one of a disposition site of the detection-target flip-flop having a longest setup time in a different functional block of the integrated circuit, or a disposition site of the detection-target flip-flop having a longest hold time in a different functional block of the integrated circuit.

The malfunction detection circuit is disposed where a malfunction would most readily occur in each functional block of the semiconductor integrated circuit, thereby enabling performing malfunction detection that is representative of the entire functional block.

Here, each of the detection circuits may have been disposed at a different one of a disposition site of the detection-target flip-flop having a longest setup time in the integrated circuit, or a disposition site of the detection-target flip-flop having a longest hold time in the integrated circuit.

The malfunction detection circuit is disposed where a malfunction would most readily occur in the semiconductor integrated circuit, thereby enabling performing malfunction detection that is representative of the entire semiconductor integrated circuit.

Here, each of the detection circuits may have been disposed at an arbitrary site on a wiring path connecting to the detection-target flip-flop that corresponds to the detection circuit.

The malfunction detection circuit is disposed at an arbitrary site on a wiring path connecting to the detection-target circuit, thereby enabling the malfunction detection circuit to be disposed away from the detection-target circuit in each functional block.

Here, each of the detection circuits may have been disposed at an arbitrary site on a wiring path connecting to the detection-target flip-flop that corresponds to the detection circuit.

The malfunction detection circuit is disposed at an arbitrary site on a wiring path connecting to the detection-target circuit, thereby enabling the malfunction detection circuit to be disposed away from the detection-target circuit in the semiconductor integrated circuit.

Here, the execution unit may include a processor, a volatile memory, and a non-volatile memory, and the processor may save data stored in the volatile memory to the non-volatile memory, as the malfunction countermeasure.

Data loss can be prevented if a reset occurs, since the data stored in the volatile memory is saved to the non-volatile memory.

The present invention is also a design method for an integrated circuit, the design method being for determining a layout of a plurality of logic cells on a mounting board in accordance with a net list and determining wiring between the logic cells on the mounting board, including: an optimization step of extracting delay information that indicates a signal delay between two of the plurality of logic cells, based on the layout of the logic cells and the wiring, and optimizing the layout of the plurality of logic cells in accordance with the extracted delay information; a selection step of selecting one or more flip-flops included in the logic cells in the optimized layout, as a detection target; and a modification step of disposing a different detection circuit in a vicinity of an area occupied by each selected flip-flop, and modify the net list so as to specify a connection relationship between the selected flip-flop and the detection circuit.

Laying out the semiconductor integrated circuit without any malfunction detection circuits, and then adding the malfunction detection circuits and modifying the layout enables efficiently designing a semiconductor integrated circuit that has malfunction detection circuits embedded within.

Here, in the selection step, the one or more selected flip-flops may be randomly selected from among a plurality of flip-flops, each of which is connected to an output of a different one of a plurality of combinational circuits included in the integrated circuit.

Randomly selecting sites where the malfunction detection circuits are to be disposed enables designing a semiconductor integrate circuit that detects malfunctions at sampled sites rather than being limited to predetermined sites on the semiconductor integrated circuit.

Here, in the selection step, the flip-flop that has a longest setup time in a function block of the integrated circuit may be selected, and the flip-flop that has a longest hold time in the function block of the integrated circuit may be selected.

Performing selection such that the malfunction detection circuits are disposed where malfunctions would most readily occur in each functional block of the semiconductor integrated circuit enables designing a semiconductor integrated circuit hat detects malfunctions in each functional block.

Here, in the selection step, the flip-flop that has a longest setup time in the integrated circuit may be selected, and the flip-flop that has a longest hold time in the integrated circuit may be selected.

Performing selection such that the malfunction detection circuits are disposed where malfunctions would most readily occur in the semiconductor integrated circuit enables designing a semiconductor integrated circuit hat detects malfunctions in the entire semiconductor integrate circuit.

### BRIEF DESCRIPTION OF DRAWINGS

These and other objects, advantages, and features of the invention will become apparent from the following description thereof taken in conjunction with the accompanying drawings, which illustrate specific embodiments of the present invention.

In the drawings:

FIG. 1 shows an overall structure of a semiconductor integrated circuit including a malfunction detection circuit pertaining to the present invention;

FIG. 2 shows a circuit structure of the malfunction detection circuit that detects a setup error in the semiconductor integrated circuit according to embodiment 1 of the present invention;

FIG. 3 is a timing chart that pertains to a logic circuit and the malfunction detection circuit that detects the setup error, and that shows timings during normal functioning, in embodiment 1 of the present invention;

FIG. 4 is a timing chart that pertains to the logic circuit and the malfunction detection circuit that detects the setup error, and that shows timings during a malfunction, in embodiment 1 of the present invention;

FIG. 5 shows a circuit structure of the malfunction detection circuit that detects a hold error in the semiconductor integrated circuit according to embodiment 1 of the present invention;

FIG. 6 is a timing chart that pertains to the logic circuit and the malfunction detection circuit that detects the hold error, and that shows timings during normal functioning, in embodiment 1 of the present invention;

FIG. 7 is a timing chart that pertains to the logic circuit and the malfunction detection circuit that detects the hold error, and that shows timings during a malfunction, in embodiment 1 of the present invention;

FIG. 8 shows a circuit structure of a clock supply circuit;

FIG. 9 shows a circuit structure of a delay adjustment circuit;

FIG. 10 is a timing chart pertaining to the delay adjustment circuit;

FIG. 11 is a chart showing malfunction detection results in a case of detecting circuit malfunctions due to a temperature variation inside or outside a semiconductor chip;

FIG. 12 shows a circuit structure of a flip-flop 500 that detects a setup error and is used in a malfunction detection circuit of a semiconductor integrated circuit according to embodiment 2 of the present invention;

FIG. 13 shows a circuit structure of a flip-flop 600, in which a clock input of an internal flip-flop 106 of the flip-flop 500 in FIG. 12 is supplied from a unit external to the flip-flop 500;

FIG. 14 shows a circuit structure of a flip-flop 700 that detects a hold error and is used in the malfunction detection circuit of the semiconductor integrated circuit according to embodiment 2 of the present invention;

FIG. 15 shows a circuit structure of a flip-flop 800, in which a clock input of an internal flip-flop 105 of the flip-flop 700 in FIG. 14 is supplied from a unit external to the flip-flop 700;

FIG. 16 shows an overview of a malfunction detection circuit included in a semiconductor integrated circuit according to embodiment 3 of the present invention;

FIG. 17 shows an overview of a malfunction detection circuit included in a semiconductor integrated circuit according to embodiment 4 of the present invention;

FIG. 18 is a timing chart that pertains to a logic circuit and a malfunction detection circuit that detects a hold error, and that shows timings during normal functioning, in embodiment 5 of the present invention;

FIG. 19 is a timing chart that pertains to the logic circuit and the malfunction detection circuit that detects a hold error, and that shows timings during a malfunction, in embodiment 5 of the present invention;

FIG. 20 is a timing chart that pertains to the logic circuit and the malfunction detection circuit that detects a setup error, and that shows timings during normal functioning, in embodiment 5 of the present invention;

FIG. 21 is a timing chart that pertains to the logic circuit and the malfunction detection circuit that detects a hold error, and that shows timings during a malfunction, in embodiment 5 of the present invention;

FIG. 22 shows a circuit structure of a malfunction detection circuit included in a semiconductor integrated circuit according to embodiment 7 of the present invention;

FIG. 23 is a timing chart that pertains to the malfunction detection circuit of the semiconductor integrated circuit, and that shows timings during normal functioning, in embodiment 7 of the present invention;

FIG. 24 is a timing chart that pertains to the malfunction detection circuit of the semiconductor integrated circuit, and that shows timings when a setup error has occurred, in embodiment 7 of the present invention;

FIG. 25 is a timing chart that pertains to the malfunction detection circuit of the semiconductor integrated circuit, and that shows timings when a hold error has occurred, in embodiment 7 of the present invention;

FIG. 26 shows a circuit structure of the malfunction detection circuit in which a separate clock input is supplied to a flip-flop 902 shown in FIG. 22;

FIG. 27 shows an overview of a malfunction detection circuit included in a semiconductor integrated circuit according to embodiment 8 of the present invention;

FIG. 28 shows an overview of a malfunction detection circuit included in a semiconductor integrated circuit according to embodiment 9 of the present invention;

FIG. 29 shows a circuit structure of a clock adjustment circuit;

FIG. 30 is a chart showing malfunction detection results in a case of detecting circuit malfunctions based on a power supply voltage variation inside or outside a semiconductor chip;

FIG. 31 is a flowchart showing a design method for a malfunction detection circuit of a semiconductor integrated circuit according to embodiment 12 of the present invention;

FIG. 32 is a flowchart showing a design method for a malfunction detection circuit of a semiconductor integrated circuit according to embodiment 13 of the present invention; and

FIG. 33 is a flowchart showing a design method for a malfunction detection circuit of a semiconductor integrated circuit according to embodiment 14 of the present invention.

### BRIEF DESCRIPTION OF CHARACTERS

101 logic circuit
102, 202 malfunction detection circuit
103, 105, 106, 108 flip-flop
104 combinational circuit
107 Ex-OR gate
109 NOT gate
301 clock tree
302 clock supply source
303 delay adjustment circuit
304 clock
305, 401, 402 buffer gate cluster
500, 600, 700, 800 flip-flop
501, 701 buffer gate cluster
1001, 1101 semiconductor integrated circuit
1002, 1003, 1004 functional block
1005-1010, 1102, 1103 flip-flop
901, 902, 903 flip-flop
904, 905 buffer gate cluster
906 Ex-OR gate
907 NOT gate
1201, 1301 semiconductor integrated circuit
1401, 1402 buffer gate cluster
1403, 1404 selector circuit

### DETAILED DESCRIPTION OF PREFERRED EMBODIMENTS

### Embodiment 1

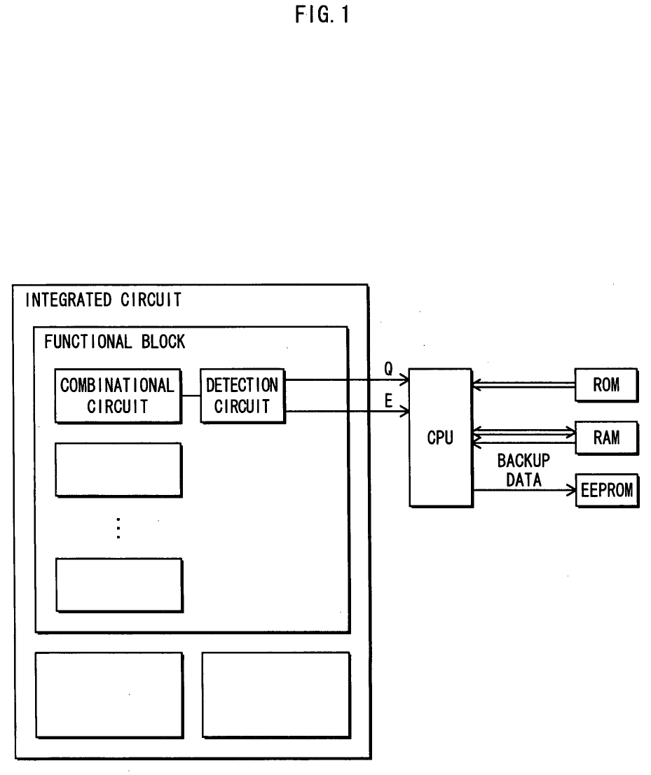

FIG. 1 shows an overall structure of a semiconductor integrated circuit pertaining to embodiment 1 of the present invention. The semiconductor integrated circuit is constituted from a plurality of functional blocks that are separated according to function, and a plurality of combinational circuits are disposed in each of the functional blocks. If a malfunction due to a temperature variation around a certain combinational circuit in a functional block is to be detected, a malfunction detection circuit is disposed in a latter stage of the combinational circuit. The malfunction detection circuit outputs a malfunction detection signal E that is separate from a signal Q that realizes the normal function of the semiconductor integrated circuit, thereby enabling a CPU (Central Processing Unit) to execute a malfunction countermeasure. For example, when reading data from a RAM (Read Only Memory) or reading/writing data from/to a RAM (Random Access Memory) during normal functioning, the CPU would backup the data in the RAM to an EEPROM (Electronically Erasable and Programmable Read Only Memory).

The following describes details of the malfunction detection circuit.

Setup Error Detection

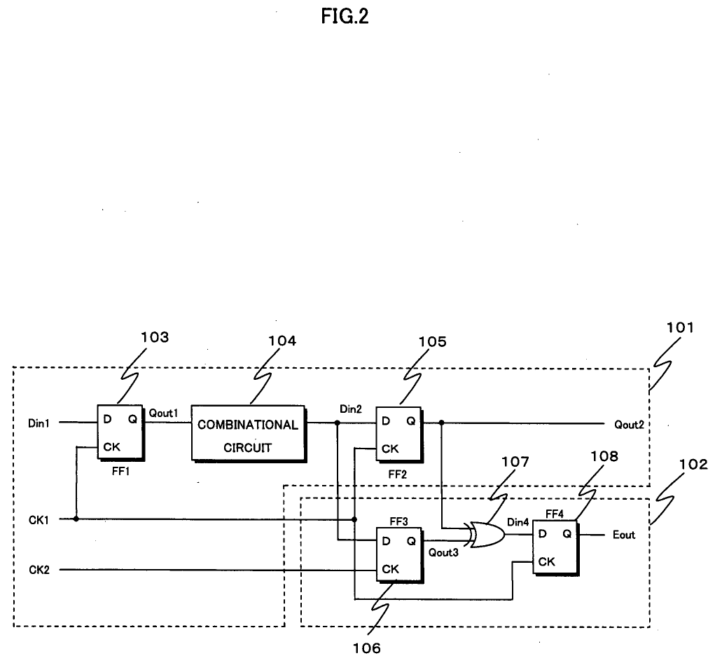

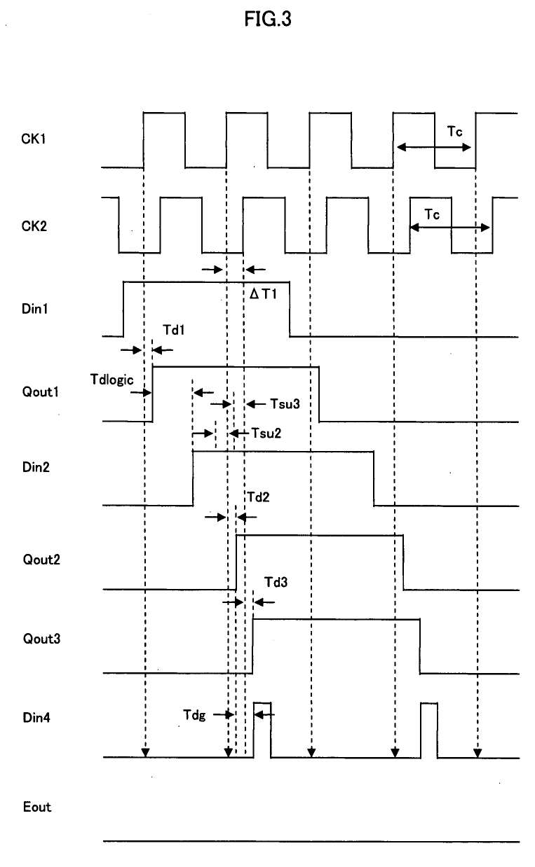

FIG. 2 shows a malfunction detection circuit of the semiconductor integrated circuit pertaining to embodiment 1 of the present invention, where the malfunction detection circuit detects a setup error. The semiconductor integrated circuit is constituted from a logic circuit 101 that realizes a function of the semiconductor chip, and a malfunction detection circuit 102 that detects a setup error in a flip-flop included in the logic circuit 101. The following describes the constituent elements of the circuits with reference to the timing chart of FIG. 3 pertaining to the logic circuit 101 and the malfunction detection circuit 102 during normal functioning.

As an example of a general logic circuit, the logic circuit 101 is constituted from flip-flops 103 and 105 that are synchronized to a clock CK₁, and a combinational circuit 104 that includes, for example, a plurality of buffer gates. The clock CK₁ is, for example, a rectangular wave having a cycle T_{c}, as shown in FIG. 3. The malfunction detection circuit 102 detects a setup error in the flip-flop 105.

The flip-flop 103 outputs an output Qₒᵤₜ₁ that is synchronized to the clock CK₁, in response to an input Dᵢₙ₁. For example, as shown in FIG. 3, the input Dᵢₙ₁ is triggered at the first rising edge of the clock CK₁, and the output Qₒᵤₜ₁ is output. Here, the cell delay of the flip-flop 103 is T_{d1}.

The combinational circuit 104 has a delay time T_{dlogic}, and for example, outputs an output Dᵢₙ₂ in response to an input Qₒᵤₜ₁, as shown in FIG. 3.

The flip-flop 105 outputs an output Qₒᵤₜ₂ that is synchronized to the clock CK₁, in response to an input Dᵢₙ₂. When a setup time T_{c}−T_{d1}−T_{dlogic} of the input Dᵢₙ₂ in response to a rising edge of the clock CK₁, and a setup time constraint Tₛᵤ₂ of the flip-flop 105 satisfy the following expression 1, the flip-flop 105 can normally trigger the input Dᵢₙ₂ at the appropriate rising edge of the clock CK₁.

T_{c}−T_{d1}−T_{dlogic}≧Tₛᵤ₂ Ex. 1

Here, for example, as shown in FIG. 3, the input Dᵢₙ₂ is triggered at the second rising edge of the clock CK₁, and the output Qₒᵤₜ₂ is output. Here, the cell delay of the flip-flop 105 is T_{d2}.

In the logic circuit 101, the input Dᵢₙ₁, the output Qₒᵤₜ₂, and the clock CK₁ are signals pertaining to the logic circuit that realizes the function of the semiconductor chip. The malfunction detection circuit 102 described hereinafter detects a malfunction in real-time as the semiconductor chip operates.

The malfunction detection circuit 102 is constituted from a flip-flop 106 that is synchronized to a clock CK₂, a flip-flop 108 that is synchronized to the clock CK₁, and an Ex-OR gate 107 that performs an exclusive logical OR operation on input signals. For example, as shown in FIG. 3, the clock CK₂ is the clock CK₁ whose phase has been delayed ΔT₁. The clock CK₂ is a clock for detecting a setup error in the flip-flop 105.

The flip-flop 106 outputs an output Qₒᵤₜ₃ that is synchronized to the clock CK₂, in response to the input Dᵢₙ₂. When a setup time (T_{c}+ΔT₁)−T_{d1}−T_{dlogic} of the input Dᵢₙ₂ in response to a rising edge of the clock CK₂, and a setup time constraint Tₛᵤ₃ of the flip-flop 106 satisfy the following expression 2, the flip-flop 106 can normally trigger the input Dᵢₙ₂ at the appropriate rising edge of the clock CK₂.

(T_{c}+ΔT₁)−T_{d1}−T_{dlogic}≧Tₛᵤ₃ Ex. 2

Here, for example, as shown in FIG. 3, the input Dᵢₙ₂ is triggered at the second rising edge of the clock CK₂, and the output Qₒᵤₜ₃ is output. Here, the cell delay of the flip-flop 106 is T_{d3}.

The setup time constraint Tₛᵤ₂ of the flip-flop 105 and the setup time constraint Tₛᵤ₃ of the flip-flop 106 are in the relationship Tₛᵤ₂≧Tₛᵤ₃.

The Ex-OR gate 107 receives an input of the output Qₒᵤₜ₂ from the flip-flop 105 and the output Qₒᵤₜ₃ from the flip-flop 106. For example, as shown in FIG. 3, the Ex-OR gate 107 outputs an output Dᵢₙ₄, which is a result of performing an exclusive logical OR operation on both input signals. Here, the cell delay of the Ex-OR gate 107 is T_{dg}.

The flip-flop 108 outputs an output Eₒᵤₜ that is synchronized to the clock CK₁, in response to an input Dᵢₙ₄. For example, as shown in FIG. 3, given that the input Dᵢₙ₄ is always “L” at a rising edge of the clock CK₁, the output Eₒᵤₜ is always “L”. The malfunction detection circuit 102 outputs such output Eₒᵤₜ while the logic circuit 101 is functioning normally.

A supply circuit and delay adjustment circuit for the clocks CK₁ and CK₂, are described later.

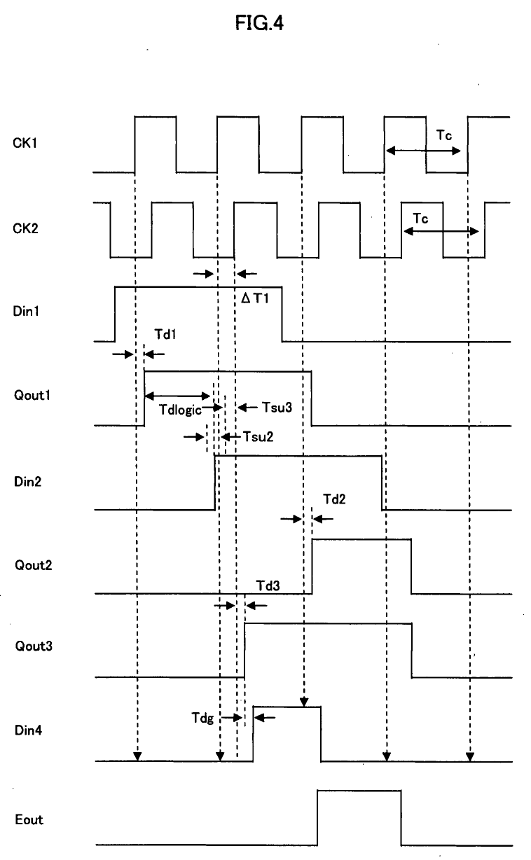

The following describes the principle by which the malfunction detecting circuit 102 detects a setup error in the logic circuit 101 with reference to the timing chart of FIG. 4 pertaining to when a malfunction has occurred.

As the temperature in the combinational circuit 104 rises, the delay time T_{dlogic} of the combinational circuit 104 increases, and when the setup time T_{c}−T_{d1}−T_{dlogic} of the input Dᵢₙ₂ in response to a rising edge of the clock CK₁, and the setup time constraint Tₛᵤ₂ of the flip-flop 105 satisfy the following expression 3, the flip-flop 105 cannot normally trigger the input Dᵢₙ₂ at the appropriate rising edge of the clock CK₁, whereby a setup error occurs.

T_{c}−T_{d1}−T_{dlogic}<Tₛᵤ₂ Ex. 3

For example, as shown in FIG. 4, the input Dᵢₙ₂ is triggered at the third rising edge of the clock CK₁, and the output Qₒᵤₜ₂ is output.

In the flip-flop 106, even if the delay time T_{dlogic} of the combinational circuit 104 increases, as long as the setup time (T_{c}+ΔT₁)−T_{d1}−T_{dlogic} of the input Dᵢₙ₂ in response to a rising edge of the clock CK₂, and the setup time constraint Tₛᵤ₃ of the flip-flop 106 satisfy the expression 2, the flip-flop 106 can normally trigger the input Dᵢₙ₂ at the appropriate rising edge of the clock CK₂. For example, as shown in FIG. 4, the input Dᵢₙ₂ is triggered at the second rising edge of the clock CK₂, and the output Qₒᵤₜ₃ is output.

When the flip-flop 105 malfunctions due to a setup error and the flip-flop 106 is functioning normally, the Ex-OR gate 107 outputs the output Dᵢₙ₄ as shown in FIG. 4. As a result, in the flip-flop 108, the output Eₒᵤₜ is “H” since the input Dᵢₙ₄ is “H” at the rising edge of the clock CK₁. This structure enables detecting a malfunction due to a setup error.

Hold Error Detection

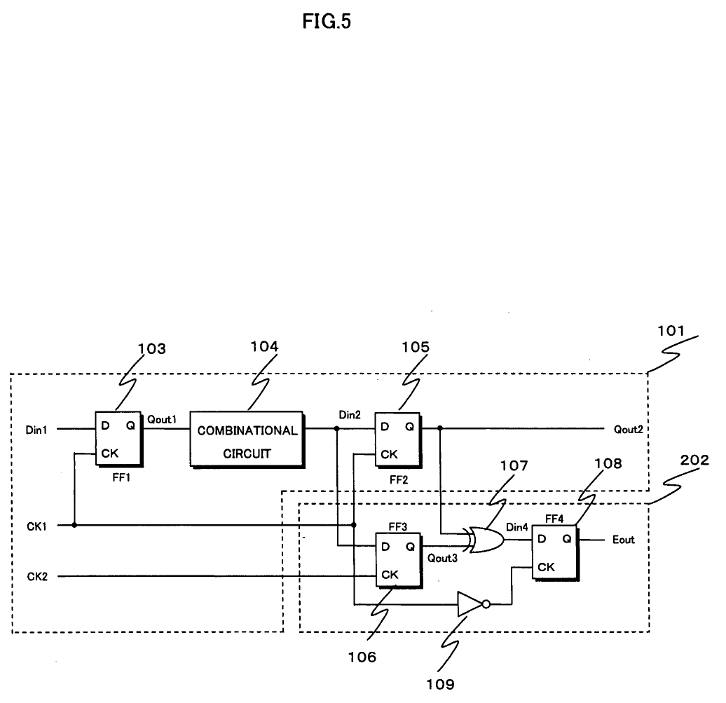

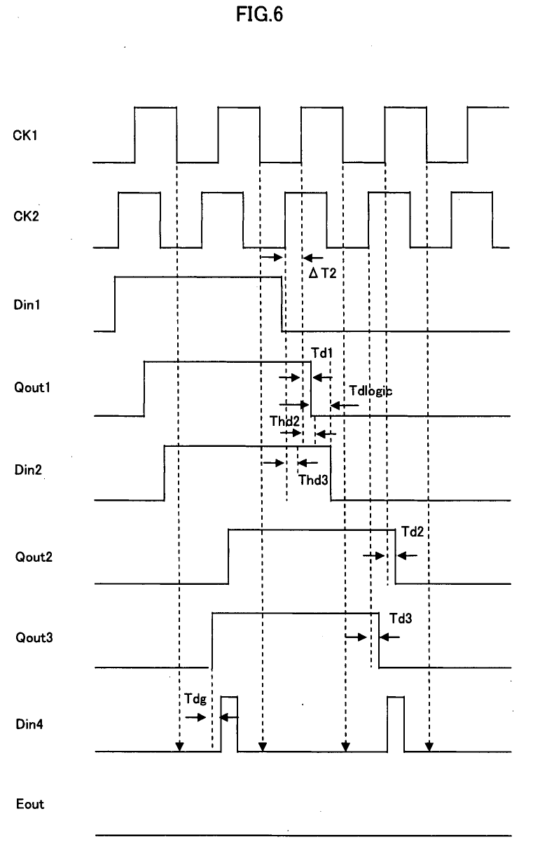

FIG. 5 shows the malfunction detection circuit of the semiconductor integrated circuit pertaining to embodiment 1 of the present invention, where the malfunction detection circuit detects a hold error. The semiconductor integrated circuit is constituted from the logic circuit 101 that realizes the function of the semiconductor chip, and the malfunction detection circuit 202 that detects a hold error in a flip-flop included in the logic circuit 101. The following describes the constituent elements of the circuits with reference to the timing chart of FIG. 6 pertaining to the logic circuit 101 and the malfunction detection circuit 202 during normal functioning.

The logic circuit 101 of FIG. 5 is similar to the logic circuit 101 of FIG. 2. The malfunction detection circuit 202 of FIG. 5 detects a hold error in the flip-flop 105.

When a hold time T_{d1}+T_{dlogic} of the input Dᵢₙ₂ in response to a rising edge of the clock CK₁, and a hold time constraint T_{hd2} of the flip-flop 105 satisfy the following expression 4, the flip-flop 105 can normally trigger the input Dᵢₙ₂ at the appropriate rising edge of the clock CK₁.

T_{d1}+T_{dlogic}≧T_{hd2} Ex. 4

Here, for example, as shown in FIG. 6, the input Dᵢₙ₂ is triggered at the fourth rising edge of the clock CK₁, and the output Qₒᵤₜ₂ is output.

The malfunction detection circuit 202 of FIG. 5 has the same circuit structure as the malfunction detection circuit 102 of FIG. 2, with the addition of a NOT gate 109 that performs a NOT operation. For example, as shown in FIG. 6, the clock CK₂ is the clock CK₁ whose phase has been advanced ΔT₂. The clock CK₂ is a clock for detecting a hold error in the flip-flop 105.

When a hold time ΔT₂+T_{d1}+T_{dlogic} of the input Dᵢₙ₂ in response to a rising edge of the clock CK₂, and a hold time constraint T_{hd3} of the flip-flop 106 satisfy the following expression 5, the flip-flop 106 can normally trigger the input Dᵢₙ₂ at the appropriate rising edge of the clock CK₂.

ΔT₂+T_{d1}+T_{dlogic}≧T_{hd3} Ex. 5

Here, for example, as shown in FIG. 6, the input Dᵢₙ₂ is triggered at the fourth rising edge of the clock CK₂, and the output Qₒᵤₜ₁ is output.

The hold time constraint T_{hd2} of the flip-flop 105 and the hold time constraint T_{hd3} of the flip-flop 106 are in the relationship T_{hd2}≧T_{hd3}.

The flip-flop 108 outputs an output Eₒᵤₜ that is synchronized to an inversion of the clock CK₁, in response to an input Dᵢₙ₄. For example, as shown in FIG. 6, given that the input Dᵢₙ₄ is always “L” at a falling edge of the clock CK₁, the output Eₒᵤₜ is always “L”. The malfunction detection circuit 202 outputs such output Eₒᵤₜ while the logic circuit 101 is functioning normally.

The supply circuit and delay adjustment circuit for the clocks CK₁ and CK₂ are described later.

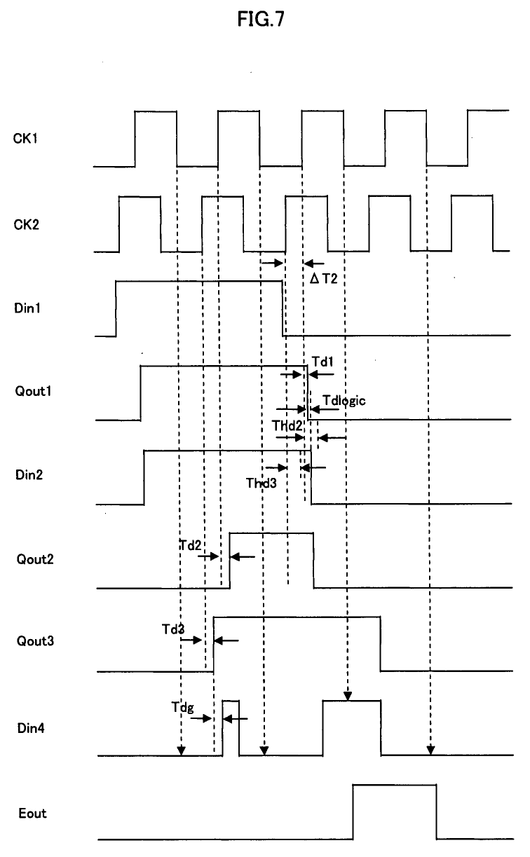

The following describes the principle by which the malfunction detecting circuit 202 detects a hold error in the logic circuit 101 of FIG. 5 with reference to the timing chart of FIG. 7 pertaining to when a malfunction has occurred.

As the temperature in the combinational circuit 104 falls, the delay time T_{dlogic} of the combinational circuit 104 decreases, and when the hold time T_{d1}+T_{dlogic} of the input Dᵢₙ₂ in response to a rising edge of the clock CK₁, and the hold time constraint T_{hd2} of the flip-flop 105 satisfy the following expression 6, the flip-flop 105 cannot normally trigger the input Dᵢₙ₂ at the appropriate rising edge of the clock CK₁, whereby a hold error occurs.

Ex. 6 T_{d1}+T_{dlogic}<T_{hd2}

For example, as shown in FIG. 7, the input Dᵢₙ₂ is triggered at the third rising edge of the clock CK₁, and the output Qₒᵤₜ₂ is output.

In the flip-flop 106, even if the delay time T_{dlogic} of the combinational circuit 104 decreases, as long as the hold time ΔT₂+T_{d1}+T_{dlogic} of the input Dᵢₙ₂ in response to a rising edge of the clock CK₂, and the hold time constraint T_{hd3} of the flip-flop 106 satisfy the expression 5, the flip-flop 106 can normally retain the input Dᵢₙ₂ at the appropriate rising edge of the clock CK₂. For example, as shown in FIG. 7, the input Dᵢₙ₂ is triggered at the fourth rising edge of the clock CK₂, and the output Qₒᵤₜ₃ is output.

When the flip-flop 105 malfunctions due to a hold error and the flip-flop 106 is functioning normally, the Ex-OR gate 107 outputs the output Dᵢₙ₄ as shown in FIG. 7. As a result, in the flip-flop 108, the output Eₒᵤₜ is “H” since the input Dᵢₙ₄ is “H” at the falling edge of the clock CK₁. This structure enables detecting a malfunction due to a hold error.

Clock Supply Circuit and Delay Adjustment Circuit

The following describes the clocks CK₁ and CK₂ shown in FIGS. 2 and 5.

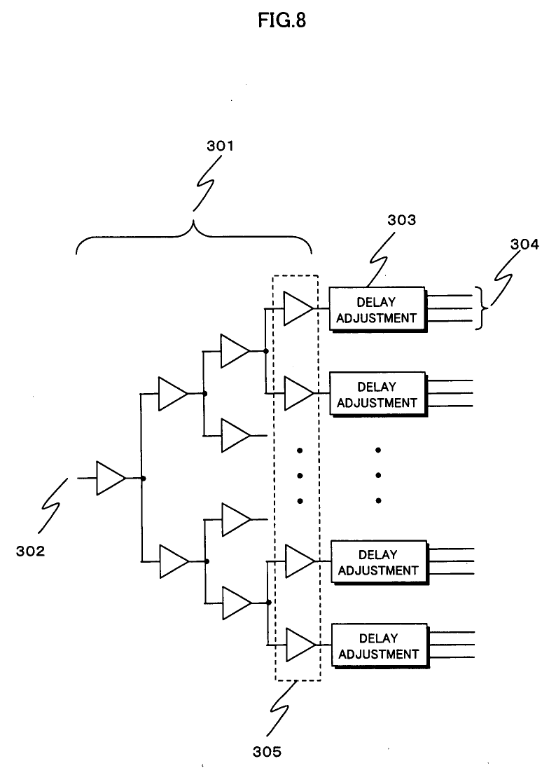

FIG. 8 shows the clock supply circuit. As shown in FIG. 8, the clock supply circuit is constituted from a clock tree 301 that sequentially branches out equally in number from a clock supply source 302 via buffer gates, and delay adjustment circuits 303 that are each attached to a different output of a buffer gate cluster 305 that is the last level of the clock tree 301. The delay adjustment circuits 303 each output three clocks 304 that have different delay times.

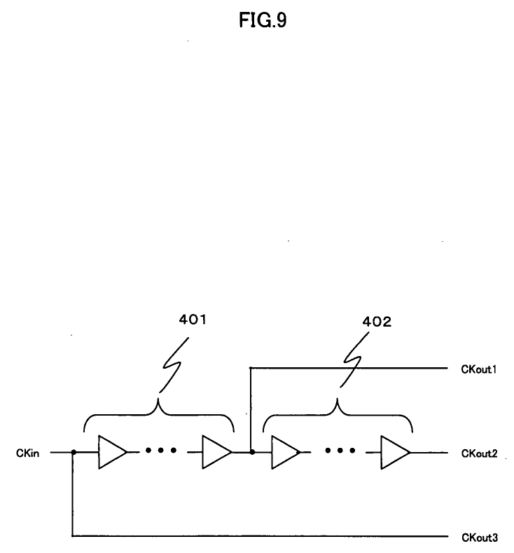

FIG. 9 shows one of the delay adjustment circuits of FIG. 8. As shown in FIG. 9, CKᵢₙ has been output from the outputs of the buffer gate cluster 305 that are the last level of the clock tree 301 in FIG. 8. The delay adjustment circuit of FIG. 9 outputs a clock CKₒᵤₜ₁ that has been delayed by a buffer gate cluster 401, a clock CKₒᵤₜ₂ that has been delayed by the buffer gate clusters 401 and 402, and a clock CKₒᵤₜ₃ that is the same as CKᵢₙ.

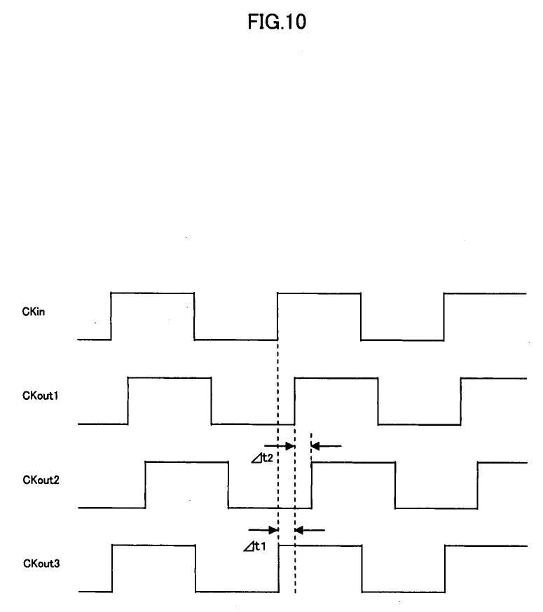

FIG. 10 is a timing chart pertaining to the delay adjustment circuit of FIG. 9. As shown in FIG. 10, the clock CKₒᵤₜ₁ is the input CKᵢₙ that has been delayed Δt₁. The clock CKₒᵤₜ₂ is the input CKᵢₙ that has been delayed Δt₁+Δt₂). The clock CKₒᵤₜ₃ is the same as the input CKᵢₙ. The clock CKₒᵤₜ₂ is the clock CKₒᵤₜ₁ that has been delayed Δt₂, and the clock CKₒᵤₜ₃ is the clock CKₒᵤₜ₁ that has been advanced Δt₁.

In FIG. 2, a setup error can be detected by supplying the clock CKₒᵤₜ₁ of FIG. 10 as CK₁, and supplying the clock CKₒᵤₜ₂ of FIG. 10 as CK₂.

In FIG. 2, a hold error can be detected by supplying the clock CKₒᵤₜ₁ of FIG. 10 as CK₁, and supplying the clock CKₒᵤₜ₃ of FIG. 10 as CK₂.

Detection Result

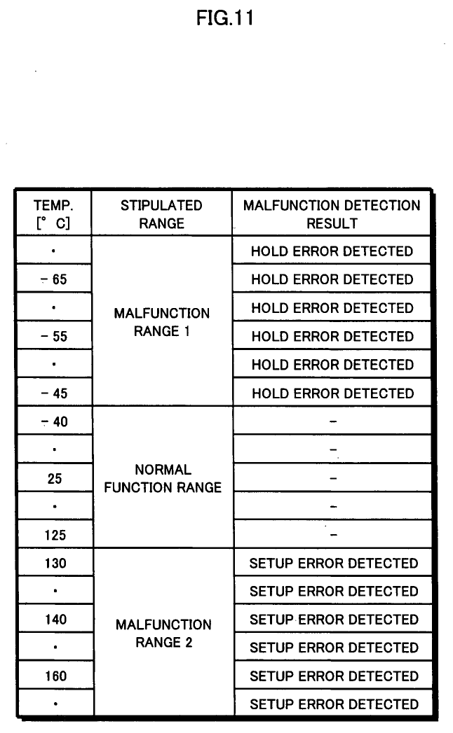

FIG. 11 shows malfunction detection results in a case of using the malfunction detection circuits of FIGS. 2 and 5 to detect circuit malfunctions due to a temperature variation inside or outside a semiconductor chip.

As shown in FIG. 11, hold errors have been detected by the malfunction detection circuit of FIG. 5 in a malfunction range 1, and setup errors have been detected by the malfunction detection circuit of FIG. 2 in a malfunction range 2.

Due to being constituted from simple logic circuits, a plurality of the malfunction detection circuits of FIGS. 2 and 5 can be disposed at arbitrary sites on the semiconductor chip.

This structure enables detecting a circuit malfunction due to a temperature variation inside or outside the semiconductor chip.

### Embodiment 2

Setup Error Detection

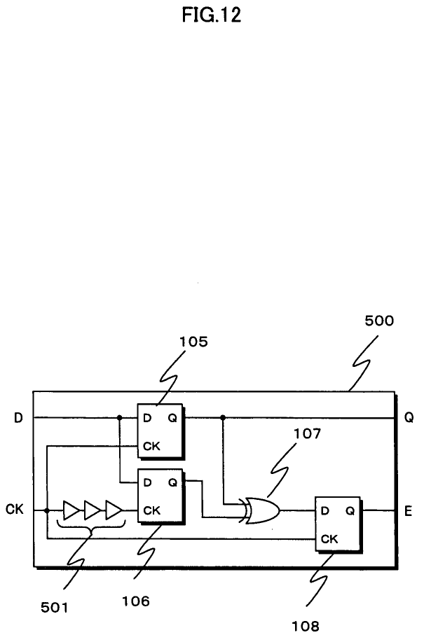

FIG. 12 shows a flip-flop 500 used by a malfunction detection circuit of a semiconductor integrated circuit pertaining to embodiment 2 of the present invention, where the flip-flop 500 detects a setup error. The flip-flop 500 has the same circuit structure as after the combinational circuit 104 of FIG. 2, with the addition of a buffer gate cluster 501. Operations of the flip-flop 500 shown in FIG. 12 during normal functioning and during a malfunction are the same as shown by the timing charts of FIGS. 3 and 4 described in embodiment 1, with the exceptions that the internal flip-flops 105 and 108 are driven by a clock CK, and the internal flip-flop 106 is driven by a clock obtained as a result of the buffer gate cluster 501 delaying the clock CK by ΔT₁. Accordingly, the flip-flop 500 always outputs “L” as a detection result E during normal functioning, and outputs “H” as a detection result E during a malfunction, thereby enabling detecting a malfunction due to a setup error.

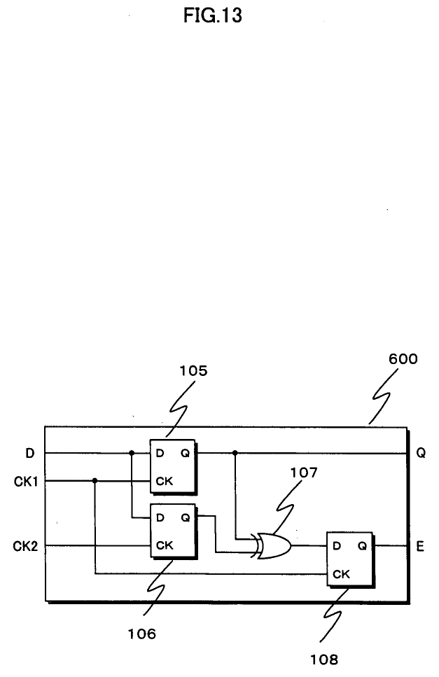

FIG. 13 shows a flip-flop 600, in which the clock input of the internal flip-flop 106 of the flip-flop 500 is supplied from a unit external to the flip-flop 500. The flip-flop 600 has the same circuit structure as after the combinational circuit 104 of FIG. 2. Operations of the flip-flop 600, which detects a setup error, during normal functioning and during a malfunction are the same as shown by the timing charts of FIGS. 3 and 4 described in embodiment 1. Accordingly, the flip-flop 600 always outputs “L” as a detection result E during normal functioning, and outputs “H” as a detection result E during a malfunction, thereby enabling detecting a malfunction due to a setup error.

Hold Error Detection

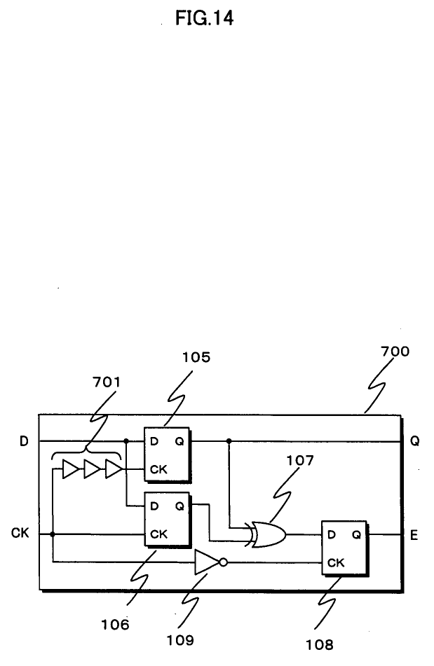

FIG. 14 shows a flip-flop 700 used by the malfunction detection circuit of the semiconductor integrated circuit pertaining to embodiment 2 of the present invention, where the flip-flop 700 detects a hold error. The flip-flop 700 has the same circuit structure as after the combinational circuit 104 of FIG. 5, with the addition of a buffer gate cluster 701. Operations of the flip-flop 700 during normal functioning and during a malfunction are the same as shown by the timing charts of FIGS. 6 and 7 described in embodiment 1, with the exceptions that the internal flip-flops 106 and 108 are driven by the clock CK and an inversion thereof respectively, and the internal flip-flop 105 is driven by a clock obtained as a result of the buffer gate cluster 701 delaying the clock CK by ΔT₂. Accordingly, the flip-flop 500 always outputs “L” as a detection result E during normal functioning, and outputs “H” as a detection result E during a malfunction, thereby enabling detecting a malfunction due to a hold error.

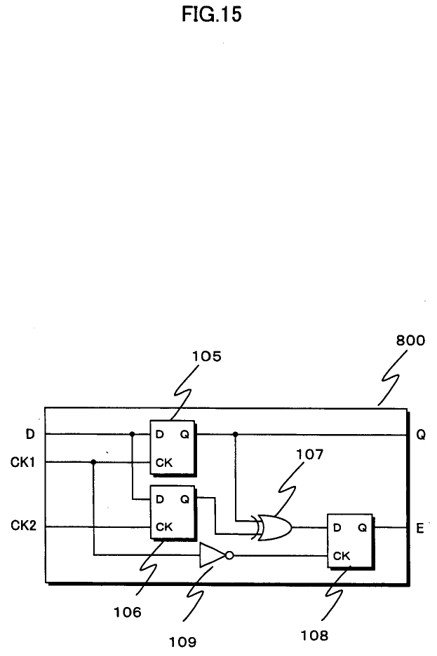

FIG. 15 shows a flip-flop 800, in which the clock input of the internal flip-flop 105 of the flip-flop 700 is supplied from a unit external to the flip-flop 700. The flip-flop 800 has the same circuit structure as after the combinational circuit 104 of FIG. 5. Operations of the flip-flop 800, which detects a hold error, during normal functioning and during a malfunction are the same as shown by the timing charts of FIGS. 6 and 7 described in embodiment 1. Accordingly, the flip-flop 800 always outputs “L” as a detection result E during normal functioning, and outputs “H” as a detection result E during a malfunction, thereby enabling detecting a malfunction due to a hold error.

Detection Result

Malfunction detection results in a case of using the malfunction detection circuits of FIGS. 12 and 15 to detect circuit malfunctions due to a temperature variation inside or outside a semiconductor chip are the same as shown in FIG. 11 described in embodiment 1.

Due to being composite flip-flops constituted from simple logic circuits, a plurality of the flip-flops of FIGS. 12 and 15 can be easily disposed at arbitrary sites on the semiconductor chip. Also, in FIGS. 12 and 14, given that the clocks CK of the flip-flops are for driving the logic circuit that realizes the function of the semiconductor chip, the flip-flops can be disposed without separately supplying clocks for malfunction detection.

This structure enables detecting a circuit malfunction due to a localized temperature variation in a wide range inside or outside the semiconductor chip.

### Embodiment 3

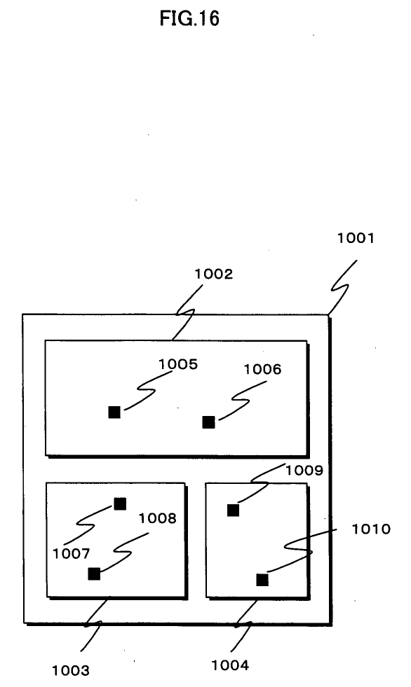

FIG. 16 shows an overview of a malfunction detection circuit of a semiconductor integrated circuit pertaining to embodiment 3 of the present invention. As shown in FIG. 16, a semiconductor integrated circuit 1001 is constituted from, for example, the three functional blocks 1002, 1003 and 1004. Among the flip-flops constituting each of the functional blocks 1002, 1003 and 1004, flip-flops 1005, 1007 and 1009 respectively thereof have the longest setup times, and flip-flops 1006, 1008 and 1010 have the longest hold times. The malfunction detection circuits described in embodiments 1 and 2 are disposed in the flip-flops that have the longest setup times and hold times in the functional blocks.

According to this structure, disposing at least two malfunction detection circuits in the semiconductor integrated circuit enables detecting a circuit malfunction due to a temperature variation inside or outside the semiconductor chip.

### Embodiment 4

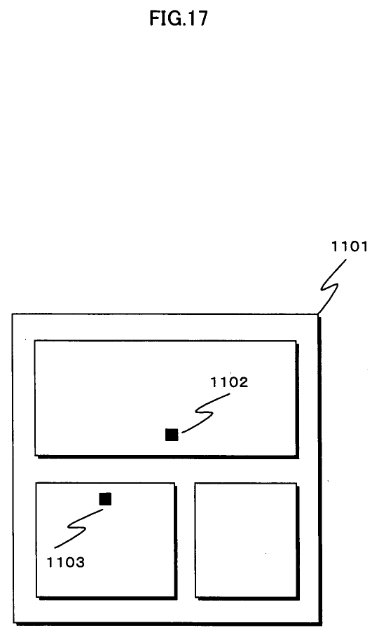

FIG. 17 shows an overview of a malfunction detection circuit in a semiconductor integrated circuit pertaining to embodiment 4 of the present invention. Among the flip-flops that constitute a semiconductor integrated circuit 1101, a flip-flop 1102 has the longest setup time, and a flip-flop 1103 has the longest hold time. The malfunction detection circuits described in embodiments 1 and 2 are disposed in the flip-flops 1102 and 1103.

According to this structure, disposing at least two malfunction detection circuits in each functional block enables detecting a circuit malfunction due to a temperature variation inside or outside the semiconductor chip.

### Embodiment 5

Hold Error Detection

A malfunction detection circuit that pre-detects a hold error in a semiconductor integrated circuit pertaining to embodiment 5 of the present invention has the same overall circuit structure as is shown in FIG. 2. The malfunction detection circuit 102 detects a hold error in the flip-flop 106.

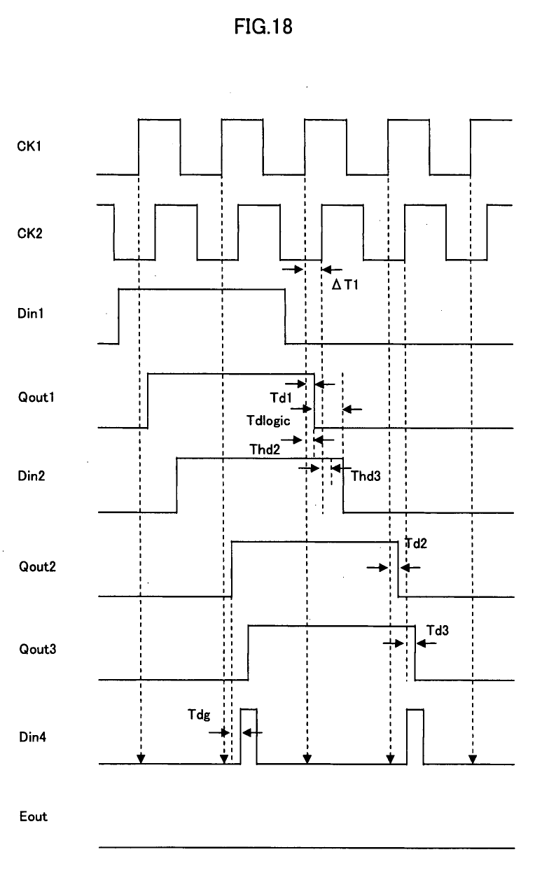

The timing chart of FIG. 18 that pertains to the logic circuit 101 and the malfunction detection circuit 102 during normal functioning is the same as FIG. 6, with the exception that the clock CK₂ for driving the malfunction detection circuit 102 is obtained by delaying the clock CK₁ by ΔT₁.

When a hold time T_{d1}+T_{dlogic} of the input Dᵢₙ₂ in response to a rising edge of the clock CK₁, and a hold time constraint T_{hd2} of the flip-flop 105 satisfy the following expression 7, the flip-flop 105 can normally retain the input Dᵢₙ₂ at the appropriate rising edge of the clock CK₁.

T_{d1}+T_{dlogic}≧T_{hd2} Ex. 7

When a hold time ΔT₁+T_{d1}+T_{dlogic} of the input Dᵢₙ₂ in response to a rising edge of the clock CK₂, and a hold time constraint T_{hd3} of the flip-flop 106 satisfy the following expression 8, the flip-flop 106 can normally retain the input Dᵢₙ₂ at the appropriate rising edge of the clock CK₂.

ΔT₁+T_{d1}+T_{dlogic}≧T_{hd3} Ex. 8

The hold time constraint T_{hd2} of the flip-flop 105 and the hold time constraint T_{hd3} of the flip-flop 106 are in the relationship T_{hd2}≦T_{hd3}.

The flip-flop 108 outputs an output Eₒᵤₜ that is synchronized to the clock CK₁, in response to an input Dᵢₙ₄. For example, as shown in FIG. 18, given that the input Dᵢₙ₄ is always “L” at a rising edge of the clock CK₁, the output Eₒᵤₜ is always “L”. The malfunction detection circuit 102 outputs such output Eₒᵤₜ while the logic circuit 101 is functioning normally.

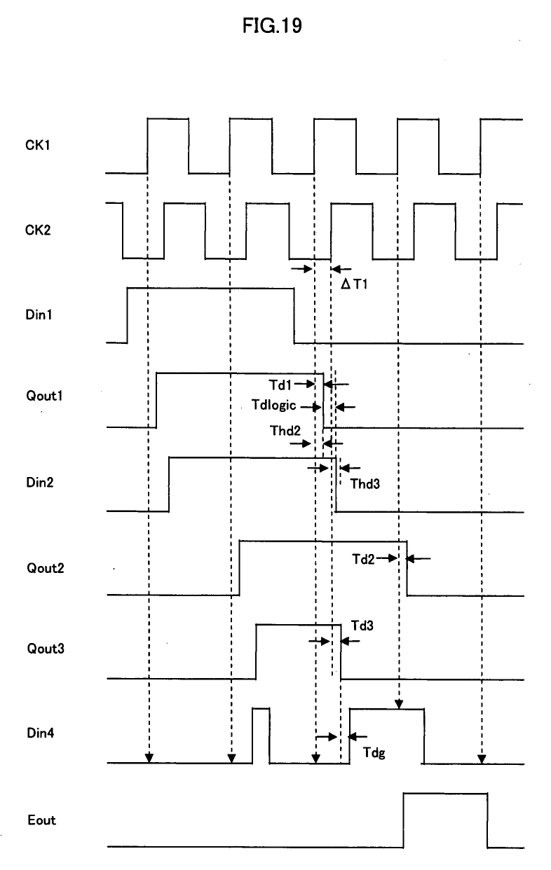

The following describes the principle by which the malfunction detecting circuit 102 pre-detects a hold error in the logic circuit 101 with reference to the timing chart of FIG. 19 pertaining to when a malfunction has occurred.

Even if the delay time T_{dlogic} of the combinational circuit 104 decreases due to a drop in the temperature in the combinational circuit 104, as long as the hold time T_{d1}+T_{dlogic} of the input Dᵢₙ₂ in response to a rising edge of the clock CK₁, and the hold time constraint T_{hd2} of the flip-flop 105 satisfy the expression 7, the flip-flop 105 can normally retain the input Dᵢₙ₂ at the appropriate rising edge of the clock CK₁.

In the flip-flop 106, when the delay time T_{dlogic} of the combinational circuit 104 decreases, and when the hold time T_{d1}+T_{dlogic}-ΔT₁ of the input Dᵢₙ₂ in response to a rising edge of the clock CK₂, and the hold time constraint T_{hd3} of the flip-flop 106 satisfy the following expression 9, the flip-flop 106 cannot normally retain the input Dᵢₙ₂ at the appropriate rising edge of the clock CK₂, whereby a hold error occurs.

T_{d1}+T_{dlogic}−ΔT₁<T_{hd3} Ex. 9

For example, as shown in FIG. 19, the input Dᵢₙ₂ is triggered at the third rising edge of the clock CK₂, and the output Qₒᵤₜ₂ is output.

When the flip-flop 105 is functioning normally and the flip-flop 106 malfunctions due to a hold error, the Ex-OR gate 107 outputs the output Dᵢₙ₄ as shown in FIG. 19. As a result, in the flip-flop 108, the output Eₒᵤₜ is “H” since the input Dᵢₙ₄ is “H” at the rising edge of the clock CK₁. This structure enables pre-detecting a malfunction due to a hold error.

Setup Error Detection

A malfunction detection circuit that pre-detects a setup error in the semiconductor integrated circuit pertaining to embodiment 5 of the present invention has the same overall circuit structure as is shown in FIG. 5. The malfunction detection circuit 202 detects a setup error in the flip-flop 106.

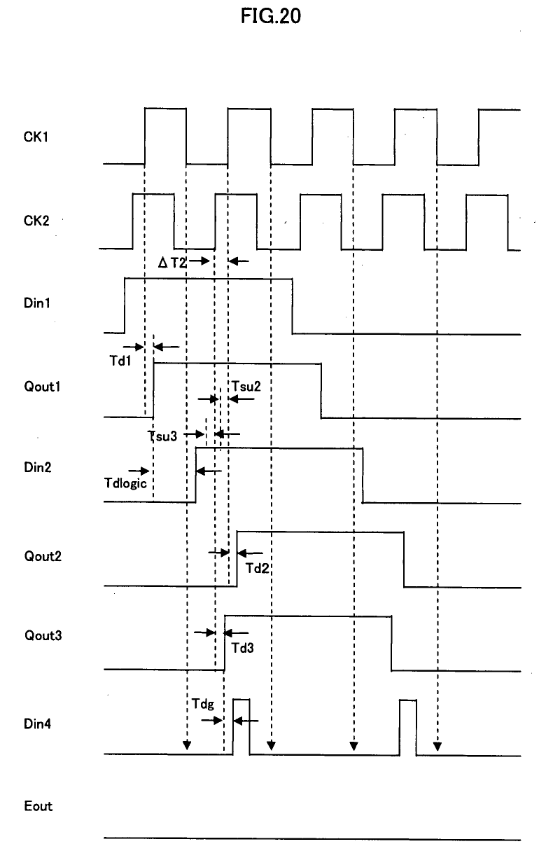

The timing chart of FIG. 20 that pertains to the logic circuit 101 and the malfunction detection circuit 202 during normal functioning is the same as FIG. 3, with the exception that the clock CK₂ for driving the malfunction detection circuit 202 is obtained by advancing the clock CK₁ by ΔT₂.

When a setup time T_{c}-T_{d1}-T_{dlogic} of the input Dᵢₙ₂ in response to a rising edge of the clock CK₁, and a setup time constraint Tₛᵤ₂ of the flip-flop 105 satisfy the following expression 10, the flip-flop 105 can normally trigger the input Dᵢₙ₂ at the appropriate rising edge of the clock CK₁.

T_{c}−T_{d1}−T_{dlogic}≧Tₛᵤ₂ Ex. 10

When a setup time (T_{c}−ΔT₂)−T_{d1}−T_{dlogic} of the input Dᵢₙ₂ in response to a rising edge of the clock CK₂, and a setup time constraint Tₛᵤ₃ of the flip-flop 106 satisfy the following expression 11, the flip-flop 106 can normally trigger the input Dᵢₙ₂ at the appropriate rising edge of the clock CK₂.

(T_{c}−ΔT₂)−T_{d1}−T_{dlogic}≧Tₛᵤ₂ Ex. 11

The setup time constraint Tₛᵤ₂ of the flip-flop 105 and the setup time constraint Tₛᵤ₃ of the flip-flop 106 are in the relationship Tₛᵤ₂≦Tₛᵤ₃.

The flip-flop 108 outputs an output Eₒᵤₜ that is synchronized to an inversion of the clock CK₁, in response to an input Dᵢₙ₄. For example, as shown in FIG. 20, given that the input Dᵢₙ₄ is always “L” at a falling edge of the clock CK₁, the output Eₒᵤₜ is always “L”. The malfunction detection circuit 202 outputs such output Eₒᵤₜ while the logic circuit 101 is functioning normally.

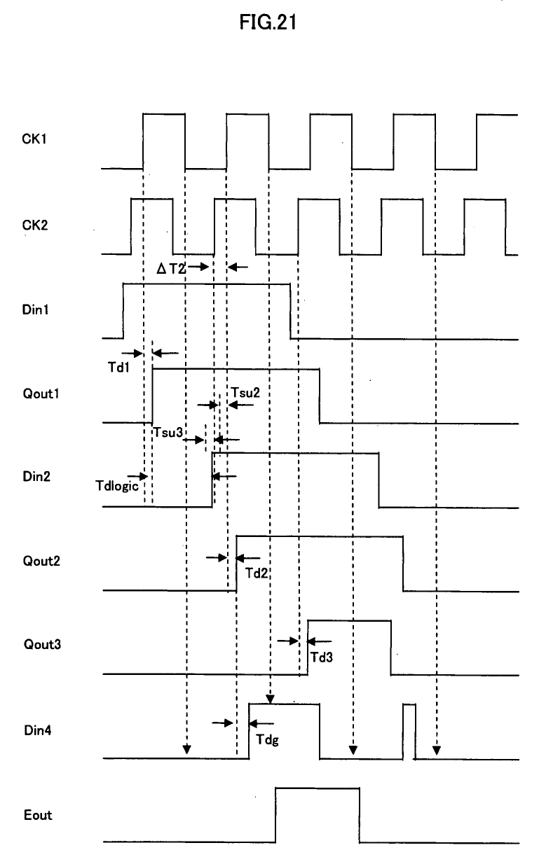

The following describes the principle by which the malfunction detection circuit 202 pre-detects a setup error in the logic circuit 101 with reference to the timing chart of FIG. 21 pertaining to when a malfunction has occurred.

Even if the delay time T_{dlogic} of the combinational circuit 104 increases due to a rise in the temperature in the combinational circuit 104, as long as the setup time T_{c}−T_{d1}−T_{dlogic} of the input Dᵢₙ₂ in response to a rising edge of the clock CK₁, and the setup time constraint Tₛᵤ₂ of the flip-flop 105 satisfy the expression 10, the flip-flop 105 can normally trigger the input Dᵢₙ₂ at the appropriate rising edge of the clock CK₁.

In the flip-flop 106, when the delay time T_{dlogic} of the combinational circuit 104 increases, and when the setup time (T_{c}−ΔT₂)−T_{d1}−T_{dlogic} of the input Dᵢₙ₂ in response to a rising edge of the clock CK₂, and the setup time constraint Tₛᵤ₃ of the flip-flop 106 satisfy the following expression 12, the flip-flop 106 cannot normally trigger the input Dᵢₙ₂ at the appropriate rising edge of the clock CK₂, whereby a setup error occurs.

(T_{c}−ΔT₂)−T_{d1}−T_{dlogic}<Tₛᵤ₃ Ex. 12

For example, as shown in FIG. 21, the input Dᵢₙ₂ is triggered at the third rising edge of the clock CK₂, and the output Qₒᵤₜ₂ is output.

When the flip-flop 105 is functioning normally and the flip-flop 106 malfunctions due to a setup error, the Ex-OR gate 107 outputs the output Dᵢₙ₄ as shown in FIG. 21. As a result, in the flip-flop 108, the output Eₒᵤₜ is “H” since the input Dᵢₙ₄ is “H” at the rising edge of the clock CK₁. This structure enables pre-detecting a malfunction due to a setup error.

### Embodiment 6

Hold Error Detection

In embodiment 6 of the present invention, a flip-flop for pre-detecting a hold error is used in a malfunction detection circuit of a semiconductor integrated circuit and has the same circuit structure as is shown in FIG. 12. Operations of the flip-flop 500 shown in FIG. 12 during normal function and during a malfunction are the same as shown by the timing charts of FIGS. 18 and 19 described in embodiment 5, with the exceptions that the internal flip-flops 105 and 108 are driven by a clock CK, and the internal flip-flop 106 is driven by a clock obtained as a result of the buffer gate cluster 501 delaying the clock CK by ΔT₁. Accordingly, “L” is always output as a detection result E during normal functioning, and “H” is always output as a detection result E during a malfunction, thereby enabling pre-detecting a malfunction due to a hold error.

Similarly to as shown in FIG. 13, a clock input of the internal flip-flop 106 of the flip-flop 500 is supplied from a unit external to the flip-flop 500. Operations of the flip-flop 600 shown in FIG. 13 during normal functioning and during a malfunction are the same as shown by the timing charts of FIGS. 18 and 19 described in embodiment 5. Accordingly, “L” is always output as a detection result E during normal functioning, and “H” is output as a detection result E during a malfunction, thereby enabling pre-detecting a malfunction due to a setup error.

Setup Error Detection

In embodiment 6 of the present invention, a flip-flop for pre-detecting a setup error is used in a malfunction detection circuit of a semiconductor integrated circuit and has the same circuit structure as is shown in FIG. 14. Operations of the flip-flop 700 shown in FIG. 14 during normal function and during a malfunction are the same as shown by the timing charts of FIGS. 20 and 21 described in embodiment 5, with the exceptions that the internal flip-flops 106 and 108 are driven by an inversion of the clock CK, and the internal flip-flop 105 is driven by a clock obtained as a result of the buffer gate cluster 701 delaying the clock CK by ΔT₁. Accordingly, “L” is always output as a detection result E during normal functioning, and “H” is always output as a detection result E during a malfunction, thereby enabling pre-detecting a malfunction due to a setup error.

Similarly to as shown in FIG. 15, a clock input of the internal flip-flop 105 of the flip-flop 700 is supplied from a unit external to the flip-flop 700. Operations of the flip-flop 700 shown in FIG. 15 during normal functioning and during a malfunction are the same as shown by the timing charts of FIGS. 20 and 21 described in embodiment 5. Accordingly, “L” is always output as a detection result E during normal functioning, and “H” is output as a detection result E during a malfunction, thereby enabling pre-detecting a malfunction due to a setup error.

The flip-flops shown in FIGS. 12 to 15 can be applied to the malfunction detection circuits described in embodiments 3 and 4.

This structure enables pre-detecting a circuit malfunction due to a temperature variation inside or outside the semiconductor chip.

### Embodiment 7

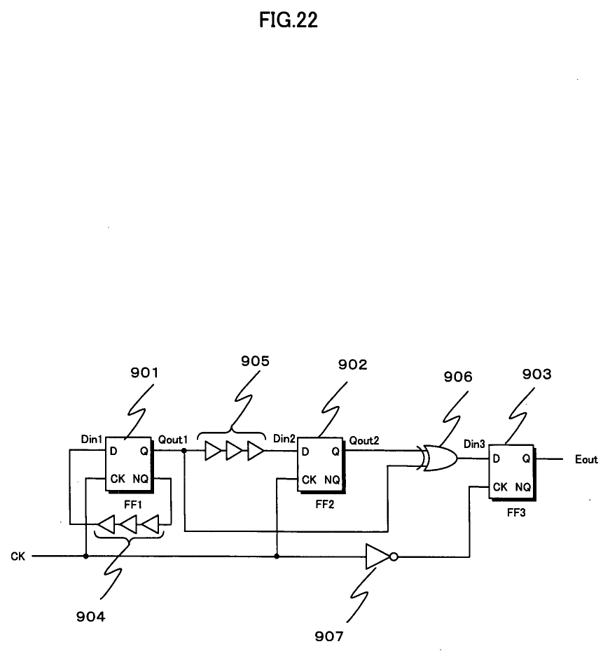

FIG. 22 shows a malfunction detection circuit of a semiconductor integrated circuit pertaining to embodiment 7 of the present invention. As shown in FIG. 22, the malfunction detection circuit of the present embodiment is constituted from flip-flops 901 and 902 that are synchronized to a clock CK, a flip-flop 903 that is synchronized to an inversion of the clock CK that has been output by the NOT gate 907, buffer gate clusters 904 and 905, and an Ex-OR gate 906. The malfunction detection circuit detects a setup error or hold error in the flip-flop 902.

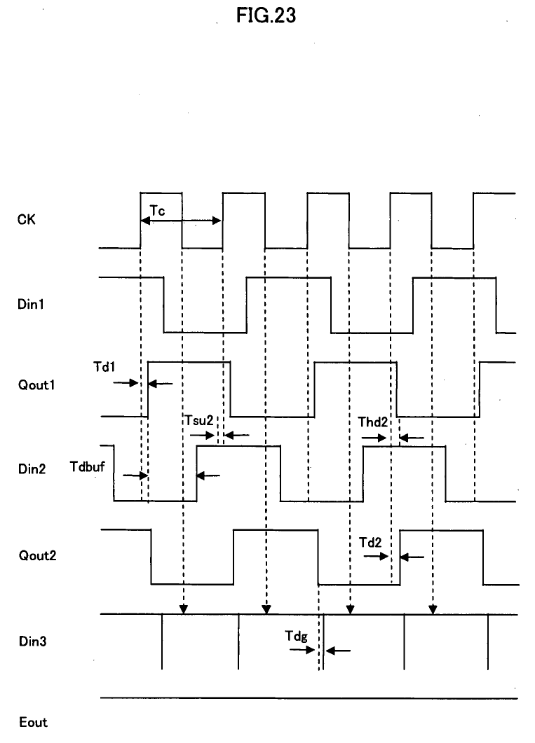

The following describes the constituent elements of the circuits with reference to the timing chart of FIG. 23 that pertains to the malfunction detection circuit during normal functioning.

The flip-flop 901 receives an input of the output Dᵢₙ₁ at input D from the buffer gate cluster 904, which receives an input of the output Qₒᵤₜ₁ from the flip-flop 901. The flip-flop 901 outputs the output Qₒᵤₜ₁ that is synchronized to the clock CK. For example, as shown in FIG. 23, when the clock CK is a rectangular wave whose cycle is T_{c}, the output Qₒᵤₜ₁ of the flip-flop 901 and the output Dᵢₙ₁ of the buffer gate cluster 904 are rectangular waves whose cycles are 2T_{c}. Here, the cell delay of the flip-flop 901 is T_{d1}. Also, the buffer gate cluster 904 has a sufficient design margin with respect to temperature variations.

The buffer gate cluster 905 is constituted such that in a case of detecting a setup error, the flip-flop 902 has the longest setup time of all of the flip-flops, and in a case of detecting a hold error, the flip-flop 902 has the longest hold time of all of the flip-flops. The buffer gate cluster 905 has a delay time T_{dbuf}, and for example, as shown in FIG. 23, outputs an output Dᵢₙ₂ in response to the input Qₒᵤₜ₁.

The flip-flop 902 outputs an output Qₒᵤₜ₂ that is synchronized to the clock CK, in response to an input Dᵢₙ₂. When a setup time T_{c}−T_{d1}−T_{dbuf} of the input Dᵢₙ₂ in response to a rising edge of the clock CK, and a setup time constraint Tₛᵤ₂ of the flip-flop 902 satisfy the following expression 13, the flip-flop 902 can normally trigger the input Dᵢₙ₂ at the appropriate rising edge of the clock CK.

T_{c}−T_{d1}−T_{dbuf}≧Tₛᵤ₂ Ex. 13

Also, when a hold time T_{d1}+T_{dbuf} of the input Dᵢₙ₂ in response to a rising edge of the clock CK₁, and a hold time constraint T_{hd2} of the flip-flop 902 satisfy the following expression 14, the flip-flop 902 can normally retain the input Dᵢₙ₂ at the appropriate rising edge of the clock CK.

T_{d1}+T_{dbuf}≧T_{hd2} Ex. 14

The Ex-OR gate 906 receives an input of the output Qₒᵤₜ₁ from the flip-flop 901 and the output Qₒᵤₜ₂ from the flip-flop 902. For example, as shown in FIG. 23, the Ex-OR gate 906 outputs an output Dᵢₙ₃, which is a result of performing an exclusive logical OR operation on both input signals. Here, the cell delay of the Ex-OR gate 906 is T_{dg}.

The flip-flop 903 outputs an output Eₒᵤₜ that is synchronized to an inversion of the clock CK, in response to an input Dᵢₙ₃. For example, as shown in FIG. 23, given that the input Dᵢₙ₃ is always “H” at a falling edge of the clock CK, the output Eₒᵤₜ is always “H”. The malfunction detection circuit outputs such output Eₒᵤₜ while the logic circuit is functioning normally.

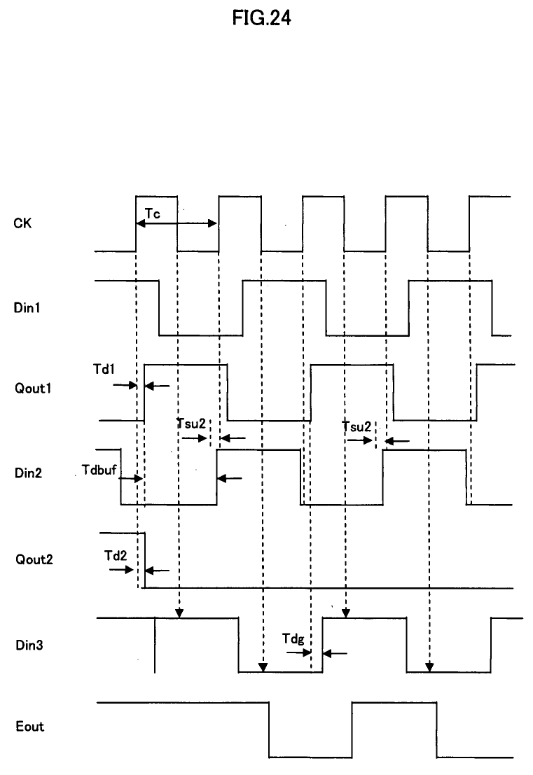

FIG. 24 shows a timing chart in a case of a setup error occurring in the malfunction detection circuit of FIG. 22. As the temperature in the buffer gate cluster 905 rises, the delay time T_{dbuf} of the buffer gate cluster 905 increases, and when the setup time T_{c}−T_{d1}−T_{dbuf} of the input Dᵢₙ₂ in response to a rising edge of the clock CK, and the setup time constraint Tₛᵤ₂ of the flip-flop 902 satisfy the following expression 15, the flip-flop 902 cannot normally trigger the input Dᵢₙ₂ at the appropriate rising edge of the clock CK, whereby a setup error occurs.

T_{c}−T_{d1}−T_{dbuf}<Tₛᵤ₂ Ex. 15

For example, as shown in FIG. 24, the Ex-OR gate 906 outputs the output Dᵢₙ₃, as a result of which the output Eₒᵤₜ of the flip-flop 903 is “L”. This enables pre-detecting a malfunction due to a setup error.

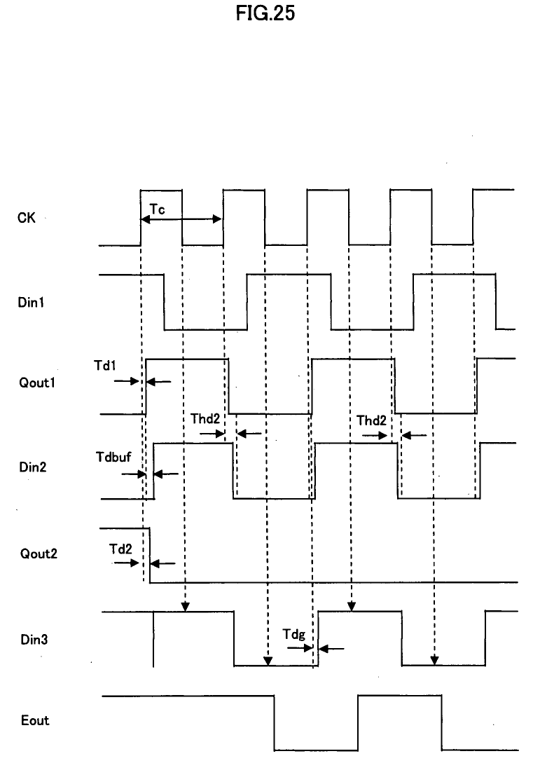

FIG. 25 shows a timing chart in a case of a hold error occurring in the malfunction detection circuit of FIG. 22. As the temperature in the buffer gate cluster 905 falls, the delay time T_{dbuf} of the buffer gate cluster 905 decreases, and when the hold time T_{d1}+T_{dbuf} of the input Dᵢₙ₂ in response to a rising edge of the clock CK, and the hold time constraint T_{hd2} of the flip-flop 902 satisfy the following expression 16, the flip-flop 902 cannot normally retain the input Dᵢₙ₂ at the appropriate rising edge of the clock CK, whereby a hold error occurs.

T_{d1}+T_{dbuf}<T_{hd2} Ex. 16

For example, as shown in FIG. 25, the Ex-OR gate 906 outputs the output Dᵢₙ₃, as a result of which the output Eₒᵤₜ of the flip-flop 903 is “L”. This enables pre-detecting a malfunction due to a hold error.

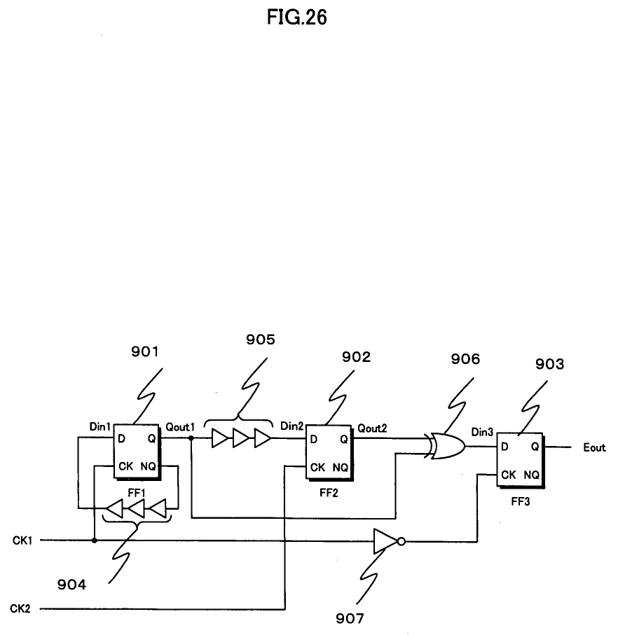

FIG. 26 shows a malfunction detection circuit in which the clock input of the flip-flop 902 of FIG. 22 is supplied separately. FIG. 26 is the same as FIG. 22, with the exceptions that the flip-flops 901 and 903 receive the clock CK₁ and an inversion thereof respectively, and the flip-flop 902 receives the clock CK₂. The clocks CK₁ and CK₂ are supplied by the clock supply circuit described in FIGS. 8, 9 and 10 in embodiment 1. In FIG. 26, the clock CKₒᵤₜ₁ of FIG. 10 is supplied as CK₁, and the clock CKₒᵤₜ₃ of FIG. 10 is supplied as CK₂, thereby enabling pre-detecting a setup error. In FIG. 26, the clock CKₒᵤₜ₁ of FIG. 10 is supplied as CK₁, and the clock CKₒᵤₜ₂ of FIG. 10 is supplied as CK₂, thereby enabling pre-detecting a hold error.

Operations of the malfunction detection circuit of FIG. 26 during normal functioning and during a malfunction are the same as shown in the timing charts of FIGS. 23, 24 and 25. “H” is always output as the detection result E during normal functioning, and “L” is output as the detection result E during a malfunction, thereby enabling pre-detecting a malfunction due to a setup error or a hold error.

Malfunction detection results in a case of using the malfunction detection circuits of FIGS. 22 and 26 to detect circuit malfunctions due to a temperature variation inside or outside a semiconductor chip are the same as shown in FIG. 11 of embodiment 1.

Due to being constituted from simple logic circuits, a plurality of the malfunction detection circuits of FIGS. 22 and 26 can be easily disposed at arbitrary sites on the semiconductor chip.

This structure enables pre-detecting a circuit malfunction due to a temperature variation inside or outside the semiconductor chip.

### Embodiment 8

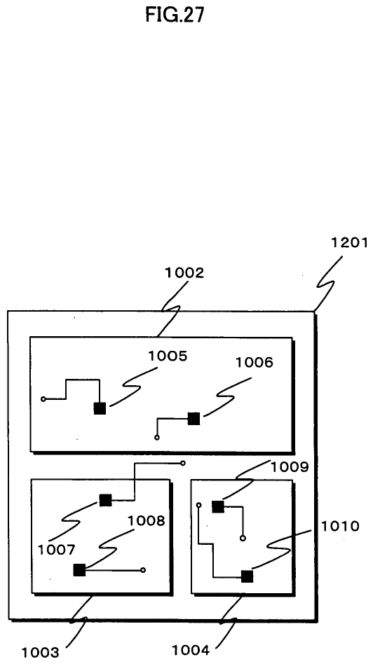

FIG. 27 shows an overview of a malfunction detection circuit of a semiconductor integrated circuit pertaining to embodiment 8 of the present invention. As shown in FIG. 27, a semiconductor integrated circuit 1201 is constituted from, for example, the three functional blocks 1002, 1003 and 1004, similarly to the semiconductor integrated circuit 1001 of FIG. 16. Among the flip-flops constituting each of the functional blocks 1002, 1003 and 1004, flip-flops 1005, 1007 and 1009 respectively thereof have the longest setup times, and flip-flops 1006, 1008 and 1010 have the longest hold times. The malfunction detection circuits described in embodiments 1 and 2 are disposed at arbitrary locations on wiring paths connecting to the flip-flops that have the longest setup times and hold times in the functional blocks.

According to this structure, disposing at least two malfunction detection circuits in each functional block enables detecting a circuit malfunction due to a temperature variation inside or outside the semiconductor chip.

### Embodiment 9

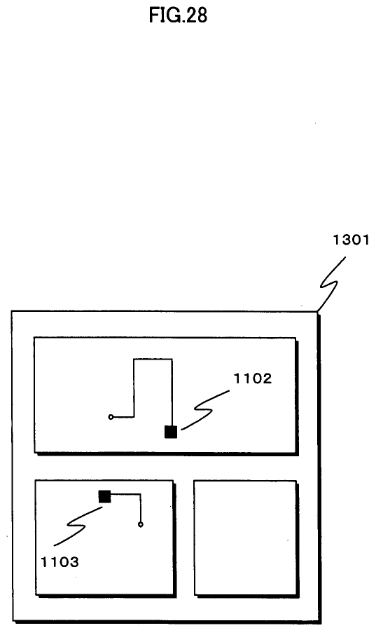

FIG. 28 shows an overview of a malfunction detection circuit of a semiconductor integrated circuit pertaining to embodiment 9 of the present invention. As shown in FIG. 28, similarly to the semiconductor integrated circuit 1101 of FIG. 17, among the flip-flops constituting the semiconductor integrated circuit 1301, a flip-flop 1102 has the longest setup time, and a flip-flop 1103 has the longest hold time. The malfunction detection circuits described in embodiments 1 and 2 are disposed at arbitrary locations on wiring paths connecting to the flip-flops 1102 and 1103.

According to this structure, disposing at least two malfunction detection circuits in the semiconductor integrated circuit enables detecting a circuit malfunction due to a temperature variation inside or outside the semiconductor chip.

### Embodiment 10

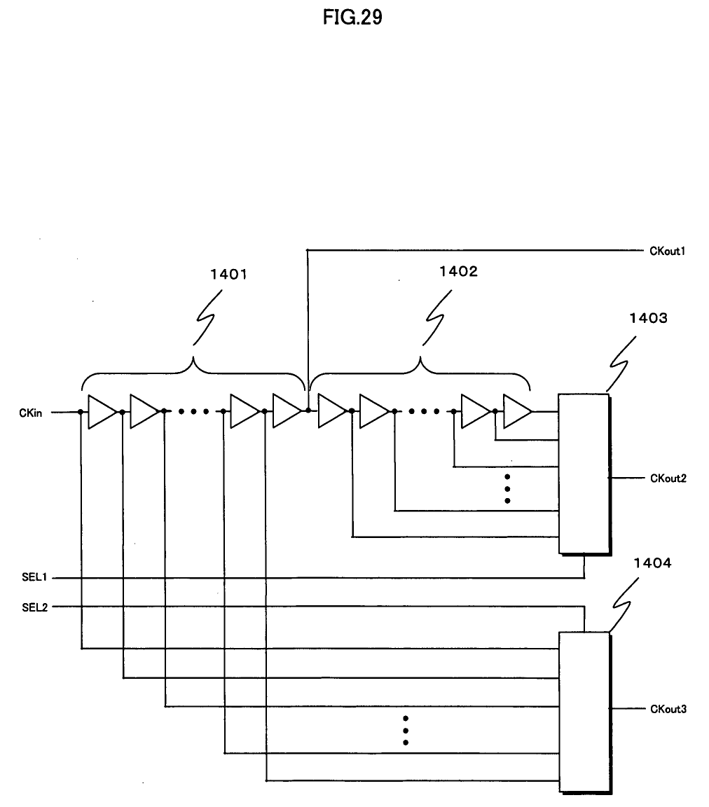

FIG. 29 shows a clock adjustment circuit of a malfunction detection circuit in a semiconductor integrated circuit pertaining to embodiment 10 of the present invention. The clock adjustment circuit is constituted from buffer gate clusters 1401 and 1402, and selector circuits 1403 and 1404. As shown in FIG. 29, CKᵢₙ is output from the buffer gate cluster 305 which is the last level of the clock tree 301 shown in FIG. 8. In the selector circuit 1403, output from the buffer gates of the buffer gate cluster 1402 is selected by SEL₁ and output as CKₒᵤₜ₂. Here, SEL₁ has a bit width capable of selecting all of the output from the buffer gate cluster 1402. In the selector circuit 1404, output from the buffer gates of the buffer gate cluster 1401 is selected by SEL₂ and output as CKₒᵤₜ₃. Here, SEL₂ has a bit width capable of selecting all of the output from the buffer gate cluster 1401.

The clock adjustment circuit of FIG. 29 can be applied to any of the malfunction detection circuits described in embodiments 1 to 9.

This structure enables detecting a circuit malfunction due to a temperature variation inside or outside the semiconductor chip.

### Embodiment 11

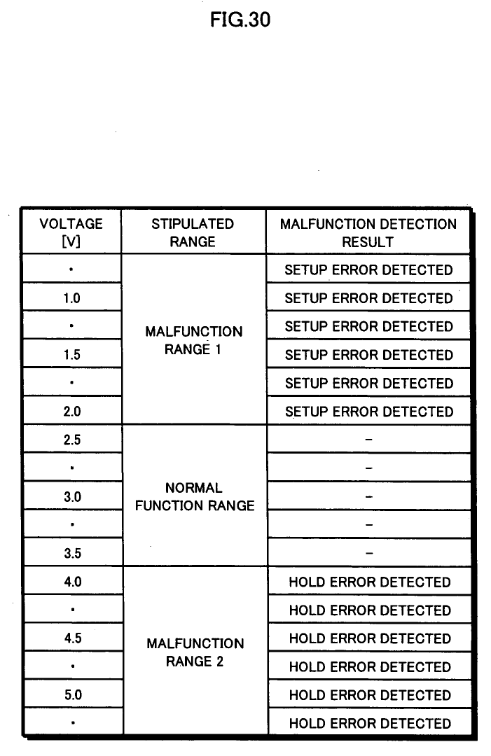

FIG. 30 shows malfunction detection results in a case of applying a malfunction detection circuit of a semiconductor integrated circuit pertaining to embodiment 11 of the present invention to a logic circuit, and detecting circuit malfunctions due to a power supply voltage variation inside or outside a semiconductor chip.

As shown in FIG. 30, in a malfunction range 1, setup errors have been detected by any of the setup-error-detecting malfunction detection circuits described in embodiments 1 to 10, and in a malfunction range 2, hold errors have been detected by any of the hold-error-detecting malfunction detection circuits described in embodiments 1 to 10.

As shown in FIG. 30, circuit malfunctions due to power supply voltages outside the specified range of the semiconductor chip can be detected by any of the malfunction detection circuits described in embodiments 1 to 10.

This structure enables detecting a circuit malfunction due to a power supply voltage variation inside or outside the semiconductor chip.

### Embodiment 12

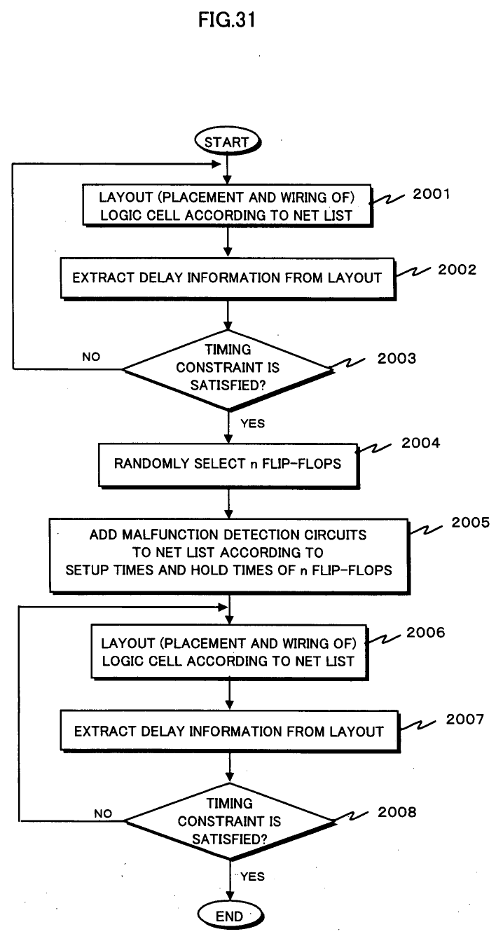

FIG. 31 is a flowchart of a design method for a malfunction detection circuit of a semiconductor integrated circuit according to embodiment 12 of the present invention.

In step 2001, a logic cell is laid out according to a net list. In step 2002, delay information pertaining to the logic cell and wiring is extracted from the layout. In step 2003, a timing constraint condition of a logic circuit in the delay information extracted in step 2002 is checked. If the timing constraint condition has not been satisfied, step 2001 is returned to. If the timing constraint condition has been satisfied in step 2003, n flip-flops are randomly selected in step 2004. In step 2005, malfunction detection circuits are selected according to the setup times and hold times of the n flip-flops selected in step 2004, and added to the net list. In step 2006, a logic cell is laid out according to the net list of step 2005. In step 2007, delay information pertaining to the logic cell and wiring is extracted from the layout. In step 2008, a timing constraint condition of a logic circuit in the delay information extracted in step 2007 is checked. If the timing constraint condition has not been satisfied, step 2006 is returned to. If the timing constraint condition has been satisfied, no more steps are performed.

This structure enables realizing a malfunction detection circuit.

### Embodiment 13

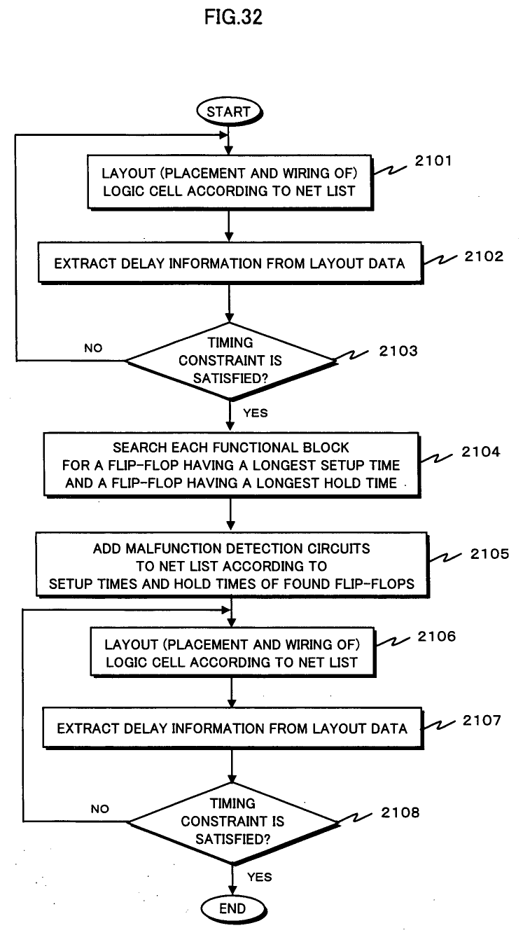

FIG. 32 is a flowchart of a design method for a malfunction detection circuit of a semiconductor integrated circuit according to embodiment 13 of the present invention.

In step 2101, a logic cell is laid out according to a net list. In step 2102, delay information pertaining to the logic cell and wiring is extracted from the layout. In step 2103, a timing constraint condition of a logic circuit in the delay information extracted in step 2102 is checked. If the timing constraint condition has not been satisfied, step 2101 is returned to. If the timing constraint condition has been satisfied in step 2103, each functional block is searched for a flip-flop that has a longest setup time and a flip-flop that has a longest hold time in step 2104. In step 2105, malfunction detection circuits are selected according to the setup times and hold times of the flip-flops found in step 2104 and added to the net list. In step 2106, a logic cell is laid out according to the net list of step 2105. In step 2107, delay information pertaining to the logic cell and wiring is extracted from the layout. In step 2108, a timing constraint condition of a logic circuit in the delay information extracted in step 2107 is checked. If the timing constraint condition has not been satisfied, step 2106 is returned to. If the timing constraint condition has been satisfied, no more steps are performed.

This structure enables realizing a malfunction detection circuit.

### Embodiment 14

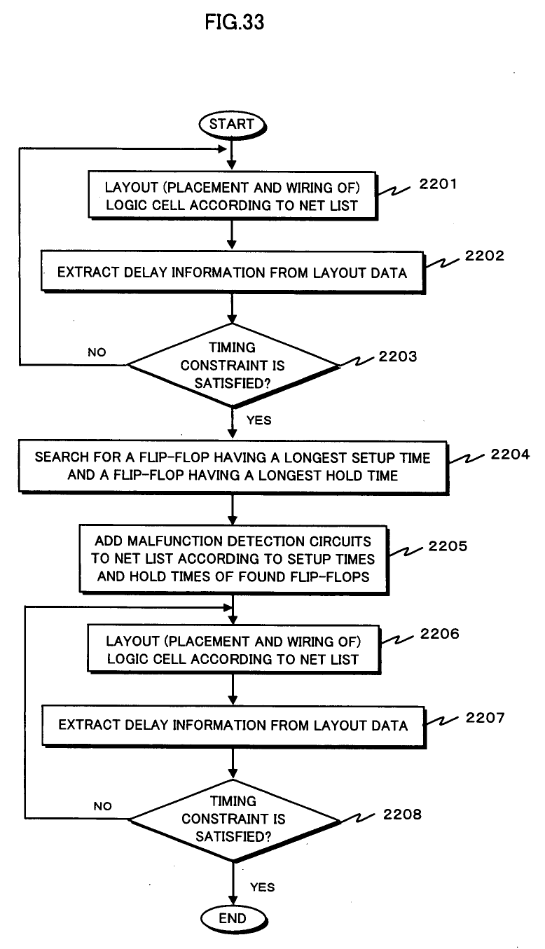

FIG. 33 is a flowchart of a design method for a malfunction detection circuit of a semiconductor integrated circuit according to embodiment 14 of the present invention.

In step 2201, a logic cell is laid out according to a net list. In step 2202, delay information pertaining to the logic cell and wiring is extracted from the layout. In step 2203, a timing constraint condition of a logic circuit in the delay information extracted in step 2202 is checked. If the timing constraint condition has not been satisfied, step 2201 is returned to. If the timing constraint condition has been satisfied in step 2203, all of the flip-flops are searched for a flip-flop that has a longest setup time and a flip-flop that has a longest hold time in step 2204. In step 2205, malfunction detection circuits are selected according to the setup times and hold times of the flip-flops found in step 2204 and added to the net list. In step 2206, a logic cell is laid out according to the net list of step 2205. In step 2207, delay information pertaining to the logic cell and wiring is extracted from the layout. In step 2208, a timing constraint condition of a logic circuit in the delay information extracted in step 2207 is checked. If the timing constraint condition has not been satisfied, step 2206 is returned to. If the timing constraint condition has been satisfied, no more steps are performed.

This structure enables realizing a malfunction detection circuit.

### INDUSTRIAL APPLICABILITY

The present invention can be applied to the detection of a malfunction in a semiconductor integrated circuit. A malfunction can be detected by a simple circuit structure, thereby improving the reliability of the semiconductor chip without the need to increase the size of the semiconductor chip in order to perform malfunction detection.

What is claimed is:

1. An integrated circuit including one or more circuit-integrated detection-target flip-flops, comprising:
one or more detection circuits, each operable to detect that a different one of the detection-target flip-flops is performing a latch operation at an appropriate clock pulse edge in a clock pulse train, and that the one of the detection-target flip-flops is performing the latch operation at an inappropriate clock pulse edge which is one of delayed behind and advanced ahead of the appropriate clock pulse edge; and
an execution unit operable to execute a malfunction countermeasure when one of the detection circuits has detected that the corresponding detection-target flip-flop has performed the latch operation at the inappropriate clock pulse edge.

2. The integrated circuit of claim 1, further comprising:
one or more combinational circuits, each operable to output an output signal, wherein
each of the detection-target flip-flops is connected to an output of a different one of the combinational circuits,
the appropriate clock pulse edge immediately follows a timing when one of a setup and a hold in the output signal output by each of the combinational circuits has ended, and
the inappropriate clock pulse edge is, among a plurality of edges in the clock pulse train, an edge at which a predetermined time constraint of one of the setup and the hold is not satisfied.

3. The integrated circuit of claim 2, wherein
each of the detection circuits includes
an other flip-flop that performs the latch operation at an edge in an other clock pulse train whose phase is one of delayed behind and advanced ahead of the clock pulse train that includes the appropriate clock pulse edge or inappropriate clock pulse edge at which the detection-target flip-flop corresponding to the detection circuit performs the latch operation, and
in each of the detection circuits, the judgment whether the predetermined time constraint of one of the setup and the hold has been satisfied is performed by executing a logic operation with use of output from the detection-target flip-flop that corresponds to the detection circuit and output from the other flip-flop included in the detection circuit.

4. The integrated circuit of claim 2, wherein
the predetermined time constraint of one of the setup and the hold is judged to not be satisfied if (i) a temperature inside or around the integrated circuit is outside a predetermined temperature range, or (ii) a power supply voltage inside or outside the integrated circuit is outside a predetermined voltage range, and
each of the detection circuits has been placed behind, from among the one or more combinational circuits in the integrated circuit, a different combinational circuit that has one of a greatest temperature variation and a greatest voltage variation.

5. The integrated circuit of claim 2, further comprising:
a clock supply circuit that includes
a plurality of buffer gates that are connected in a tree configuration, and
a plurality of delay adjustment circuits, each operable to perform delay adjustment on an output of a different one of the buffer gates in a last level of the tree configuration, wherein
in each of the detection circuits, the latch operation has been performed by the other flip-flop in accordance with one of the outputs on which the delay adjustment has been performed.

6. The integrated circuit of claim 3, wherein
in each of the detection circuits, a predetermined time constraint of the other flip-flop included in the detection circuit is longer than the predetermined time constraint of the detection-target flip-flop that corresponds to the detection circuit.

7. The integrated circuit of claim 1, wherein
each of the detection circuits has been disposed at a different one of (i) a disposition site of the detection-target flip-flop having a longest setup time in a different functional block of the integrated circuit, or (ii) a disposition site of the detection-target flip-flop having a longest hold time in a different functional block of the integrated circuit.

8. The integrated circuit of claim 1, wherein
each of the detection circuits has been disposed at a different one of (i) a disposition site of the detection-target flip-flop having a longest setup time in the integrated circuit, or (ii) a disposition site of the detection-target flip-flop having a longest hold time in the integrated circuit.

9. The integrated circuit of claim 7, wherein
each of the detection circuits has been disposed at an arbitrary site on a wiring path connecting to the detection-target flip-flop that corresponds to the detection circuit.

10. The integrated circuit of claim 8, wherein
each of the detection circuits has been disposed at an arbitrary site on a wiring path connecting to the detection-target flip-flop that corresponds to the detection circuit.

11. The integrated circuit of claim 1, wherein
the execution unit includes
a processor,
a volatile memory, and
a non-volatile memory, and
the processor saves data stored in the volatile memory to the non-volatile memory, as the malfunction countermeasure.

12. A design method for an integrated circuit, the design method being for determining a layout of a plurality of logic cells on a mounting board in accordance with a net list and determining wiring between the logic cells on the mounting board, comprising:
an optimization step of extracting delay information that indicates a signal delay between two of the plurality of logic cells, based on the layout of the logic cells and the wiring, and optimizing the layout of the plurality of logic cells in accordance with the extracted delay information;
a selection step of selecting one or more flip-flops included in the logic cells in the optimized layout, as a a detection target; and
a modification step of disposing a different detection circuit in a vicinity of an area occupied by each selected flip-flop, and modify the net list so as to specify a connection relationship between the selected flip-flop and the detection circuit.

13. The design method of claim 12, wherein
in the selection step, the one or more selected flip-flops is randomly selected from among a plurality of flip-flops, each of which is connected to an output of a different one of a plurality of combinational circuits included in the integrated circuit.

14. The design method of claim 12, wherein
in the selection step, the flip-flop that has a longest setup time in a function block of the integrated circuit is selected, and the flip-flop that has a longest hold time in the function block of the integrated circuit is selected.

15. The design method of claim 12, wherein
in the selection step, the flip-flop that has a longest setup time in the integrated circuit is selected, and the flip-flop that has a longest hold time in the integrated circuit is selected.
